(19) United States
(12) Patent Application Publication
(10) Pub. No.: US 2024/0170252 A1
(43) Pub. Date: May 23, 2024

(54) MULTI-BEAM GENERATING UNIT WITH INCREASED FOCUSING POWER

(71) Applicant: Carl Zeiss MultiSEM GmbH, Oberkochen (DE)

(72) Inventors: Yanko Sarov, Aalen (DE); Dirk Zeidler, Oberkochen (DE); Thomas Schmid, Aalen (DE); Georg Kurij, Ulm (DE); Marcus Kaestner, Wittislingen (DE); Ulrich Bihr, Dirgenheim (DE); Wolfgang Singer, Aalen (DE)

(21) Appl. No.: 18/423,564

(22) Filed: Jan. 26, 2024

Related U.S. Application Data
(63) Continuation of application No. PCT/EP2022/064275, filed on May 25, 2022.

(30) Foreign Application Priority Data
Aug. 10, 2021 (DE) 102021208700.0

(51) Int. Cl. H01J 37/317; H01J 37/09; H01J 37/12; H01J 37/153; H01J 37/28; H01J 37/30

(52) U.S. Cl. CPC H01J 37/3177; H01J 37/09; H01J 37/12; H01J 37/153; H01J 37/3007; H01J 37/28; H01J 2237/0453; H01J 2237/1205; H01J 2237/1516; H01J 2237/1534; H01J 2237/20207; H01J 2237/30488

(57) ABSTRACT

A multi-beam generation unit for a multi-beam system has larger individual focusing power for each of a plurality of primary charged particle beamlets. The multi-beam generation unit comprises an active terminating multi-aperture plate. The terminating multi-aperture plate can be used for a larger focusing range for an individual stigmatic focus spot adjustment of each beamlet of a plurality of primary charged particle beamlets.

### CROSS-REFERENCE TO RELATED APPLICATIONS

The present application is a continuation of, and claims benefit under 35 USC 120 to, international application PCT/EP2022/064275, filed May 25, 2022, which claims benefit under 35 USC 119 of German Application No. 10 2021 208 700.0, filed Aug. 10, 2021.

The entire disclosure of each these applications is incorporated by reference herein.

### FIELD

The disclosure relates to multi-beam raster units such as multi-beam generating units and multi-beam deflector units of a multi-beam charged particle microscope.

### BACKGROUND

WO 2005/024881 A2 discloses an electron microscope system which operates with a multiplicity of electron beamlets for the parallel scanning of an object to be inspected with a bundle of electron beamlets. The bundle of electron beamlets is generated by directing a primary electron beam onto a first multi-aperture plate, which has a multiplicity of openings. One portion of the electrons of the electron beam is incident onto the multi-aperture plate and is absorbed there, and another portion of the beam transmits the openings of the multi-aperture plate and thereby in the beam path downstream of each opening an electron beamlet is formed whose cross section is defined by the cross section of the opening. Furthermore, suitably selected electric fields which are provided in the beam path upstream and/or downstream of the multi-aperture plate cause each opening in the multi-aperture plate to act as a lens on the electron beamlets passing the opening so that said each electron beamlet is focused in a surface which lies at a distance from the multi-aperture plate. The surface in which the foci of the electron beamlets are formed is imaged by downstream optics onto the surface of the object or sample to be inspected. The primary electron beamlets trigger secondary electrons or backscattered electrons to emanate as secondary electron beamlets from the object, which are collected and imaged onto a detector. Each of the secondary beamlets is incident onto a separate detector element so that the secondary electron intensities detected therewith provide information relating to the sample at the location where the corresponding primary beamlet is incident onto the sample. The bundle of primary beamlets is scanned systematically over the surface of the sample and an electron microscopic image of the sample is generated in the usual way for scanning electron microscopes. The resolution of a scanning electron microscope is generally limited by the focus diameter of the primary beamlets incident onto the object. Consequently, in multi-beam electron microscopy all the beamlets should form the same small focus on the object.

It is understood that the system and method illustrated in WO 2005/024881 in great detail at the example of electrons can be applicable in general to charged particles.

Multiple beamlets for a multi-beam, charged particle microscope (MCPM) are generated in a multi-beam generating unit. Multi-beam charged particle microscopes (MCPM) commonly use both micro-optical (MO) elements and macroscopic elements in a charged particle projection system.

Multi-beam generating units generally comprise elements for splitting, partially absorbing, and influencing a beam of charged particles. As a result, a plurality of beamlets of charged particles in a predefined raster configuration is generated. Multi-beam generating units generally comprise micro-optical elements, such as the first multi-aperture plate, further multi-aperture plates and micro-optical deflection elements, and macroscopic elements, such as lenses, in a special element design and special arrangement.

A multi-beam generating unit can be formed in an assembly of two or more parallel planar substrates or wafers, for example created by silicon micro structuring. During use, a plurality of electrostatic optical elements is formed by aligned apertures in at least two of such planar substrates or wafers. Some of the apertures may be equipped with one or more vertical electrodes, arranged with axial symmetry around the apertures, creating for example electrostatic lens arrays. The optical aberrations of such electrostatic lens arrays are known to be highly sensitive to the manufacturing inaccuracies of the plurality of apertures.

For generation of predefined electrostatic optical elements, it can be desirable to precisely control the plurality of electrodes, for example the geometry of the electrodes and the lateral alignment with respect to each beamlet of a plurality of charged particle beamlets, as well the distances between the electrodes in direction of a transmitting plurality of charged particle beamlets. Deviations in the fabrication processes of planar substrates, the electrodes and the assembly of planar substrates generate aberrations of the electrostatic optical elements and cause aberrations such as aberrations of the individual beamlets or deviations from the predefined raster configuration of the beamlets.

Multi-beam microscopes for wafer inspection form a plurality of focus spots of the plurality of primary charged particle beamlets on a wafer surface. The imaging lenses generate a field curvature, leading to a deviation of the plurality of primary focus points from the planar wafer surface. Recently it has been discovered that multi-beam microscopes with a beam splitter can exhibit further a tilt of the image plane. Even after correction of the field curvature, the image plane, in which the plurality of primary focus points is generated, can be tilted with respect to the wafer surface. The orientation of the image plane tilt can depend on the Larmor rotation of the plurality of primary charged particle beamlets, induced by the magneto-optical lenses. Image plane tilt and field curvature add to large deviations of the focus positions from a wafer surface. Certain known multi-beam generating units do not provide sufficient stroke for individually changing the focus positions of each primary charged particle beamlet with high accuracy, as desired for wafer inspection tasks.

The multi-aperture plates with electrodes are typically formed by layer deposition and etching techniques, and a stack of different layers is formed. For a larger stroke, higher voltages are typically provided to the electrostatic lenses. Inhomogeneities of the layer deposition and leakages of electrical fields lead to inhomogeneous electron optical properties of the electrostatic elements over a multi-aperture plate. With the conventional arrangement of electrodes in multi-aperture elements, stray field may be generated, which influence the performance of electrooptical elements in an uncontrolled way. In certain known multi-aperture stacks, the optical performance is generally limited.

Multi-aperture plates can comprise thin membranes, fabricated for example from wafers by thinning processes. The deformation of membranes, generated during fabrication or induced e.g. by thermal expansion, can cause different distances between several multi-aperture plates and thus a difference in the plurality of electrostatic elements formed during use between at least two multi-aperture plates. A change of deformation of membranes can further introduce a deviation of a field curvature of the plurality of focus points of the beamlets, or a deviation of telecentricity properties of the plurality of beamlets.

An approach for improving the theoretical performance of multi aperture arrays has previously been considered. For example, US 2003/0209673 A1 discloses an approach to reduce crosstalk between the plurality of primary charged particle beamlets. US 2003/0209673 A1 discloses an electrostatic Einzel-lens array for a plurality of electron beamlets with reduced cross talk. The electrostatic Einzel-lens array is arranged in an electron beam path downstream of an aperture array and comprises an upper electrode, middle electrodes, and a lower electrode of the Einzel-lenses, wherein each pair of electrodes is spaced apart by a large distance of 100 μm. Crosstalk is reduced by shielding electrodes, provided between upper electrode and middle electrodes and middle electrodes and lower electrode. In another example, an approach for reduction of design aberrations are considered. DE 10 2014 008 083 A1, filed on May 30, 2014 or corresponding U.S. Pat. No. 9,552,957 B2 show an example of a multi-aperture plate comprising an array of lenses with reduced spherical aberration. A reduction of design aberrations is achieved by lens apertures being larger compared to a beam diameter. DE 10 2014 008 083 A1 proposes a distance between multi-aperture plates in a range of 0.1 to 10 times of aperture diameters to avoid a charging effect on the electrodes, yet alone this large range has turned out to be not enough to always prevent unwanted charging effects of electrodes from scattered charged particles.

### SUMMARY

The present disclosure proposes a charged particle beam system which operates with a multiplicity of charged particle beams and can be used to achieve a higher imaging performance, such as a better resolution and narrower range of resolution for each beamlet of the plurality of beamlets.

The present disclosure seeks to provide a multi-beam generating unit with a relatively large stroke for individually changing each focus position of each primary charged particle beamlet. The present disclosure also seeks to provide a multi-aperture plate with which the focus positions of each primary beamlet can be adjusted with higher precision and minimized aberrations. The present disclosure also seeks to provide multi-beam generating units capable to form well defined beamlets with small focus point diameters, with larger focusing power and high focusing precision, and with minimal residual aberrations. With the new arrangement and optimized layout of the multi-beam generating or multi-beam raster unit, a plurality of focus points of beamlets can be generated in the predefined raster configuration and with a large axial variation, allowing the compensation of a large field curvature of a multi-beam inspection system. In a similar way, a multi-beam deflecting unit is provided, which is capable to deflect beamlets with high precision without introducing or increasing aberrations of the beamlets.

The present disclosure seeks to provide a design of a multi-beam raster unit such as a multi beam generating or multi-beam deflecting unit with large individual optical power and which is less sensitive to deviations and does not significantly introduce or increase aberrations and generates during operation less unwanted leakage fields. The present disclosure also seeks to provide multi-beam raster units which provide during use a higher precision in focus position control.

The present disclosure seeks to provide multi-beam raster units comprising at least three multi-aperture plates, including to provide a fabrication process for a multi-aperture plate which is less sensitive to deviations, generates low aberrations and less scattered particles, and which allows fabrication of a multi beam generating or multi-beam deflecting unit with high stability and repeatability. The new arrangement of the multi-aperture plates in the multi-beam raster unit can allow a large range of focusing power for individually influencing the focus spot positions of the plurality of charged particle beamlets generated by the multi-beam raster unit.

According to a first aspect, the disclosure provides a multi-beam generation unit for a multi-beam system comprises a filter plate with a plurality of first apertures for generating a plurality of primary charged particle beamlets form an incident, parallel primary charged particle beam, the filter plate connected during use to a ground level. The primary charged particle beamlets are formed by transmitting the plurality of first apertures, while the majority of charged particles of the incident primary charged particle beam are absorbed a conductive shielding layer on the beam entrance side of the filter plate. The multi-beam generation unit further comprises a terminating multi-aperture plate. The terminating multi-aperture plate is arranged in the order of the propagation direction of the incident primary charged particle beam downstream of the filter plate and comprises a plurality of terminating apertures. At each of a terminating aperture, a primary charged particle beamlet leaves the multi-beam generation unit. Each terminating aperture comprises a first plurality of individually addressable electrodes arranged in the circumference of each of the plurality of terminating apertures. Downstream of the terminating multi-aperture plate, the multi-beam generation unit comprises or is connected to a condenser lens with a condenser electrode with a single aperture configured for transmitting during use the plurality of primary charged particle beamlets. The condenser electrode is configured for generating during use a plurality of electrostatic micro-lens fields, which are penetrating each of the plurality of terminating apertures. The multi-beam generation unit) further comprises a control unit. The control unit is configured to individually control the condenser electrode and each of the first plurality of individually addressable electrodes to influence the penetration depth and/or shape of each of the plurality of electrostatic micro-lens fields, thereby independently adjusting a lateral and axial focus position of each of the plurality of primary charge particle beamlets. The plurality of primary charge particle beamlets therefore form during use a plurality of focus points in an intermediate, curved image surface. The intermediate, curved image surface is curved and has a tilt component to pre-compensate a field curvature and an image plane tilt of the multi-beam system.

In an example, the first plurality of individually addressable electrodes is formed as a first plurality of electrostatic cylinder or ring electrodes, each cylinder or ring electrode arranged in the circumference of one of the terminating apertures, configured for generating during use a suction field or a depression field. Thereby the penetration depth of each of the plurality of electrostatic micro-lens fields is either reduced or increased in a corresponding terminating aperture and a focal length can be adjusted in a wide range. Thereby an axial position of a focus point of an individual primary charged particle beamlet can be changed in a wide range.

In another example, the first plurality of individually addressable electrodes is formed as a first plurality of electrostatic multi-pole electrodes, each multi-pole electrode arranged in the circumference of one of the plurality of terminating apertures, configured for generating during use a suction field, a depression field and/or a deflection field and/or an aberration correction field. Thereby not only the penetration depth of each of the plurality of electrostatic micro-lens fields is either reduced or increased, but also the lateral position is changed as well as the shape of each of the plurality of electrostatic micro-lens fields in a corresponding terminating aperture. Thereby, for example an aberration like astigmatism can be corrected and a lateral position of a focus point of an individual primary charged particle beamlet can be changed by the deflecting mechanism.

The terminating multi-aperture plate may comprise a first, terminating electrode layer comprising the first plurality of individually addressable electrodes and a second electrode layer, isolated from the first plurality of individually addressable electrodes and arranged upstream of the first, terminating electrode layer. The second electrode layer is during use connected to ground level for forming a ground electrode layer. In another form, the terminating multi-aperture plate is made of a single electrode layer.

The multi-beam generation unit may further comprise at least a second multi-aperture plate or ground electrode plate with a plurality of second apertures. The second multi-aperture plate is forming during use a first ground electrode. The second multi-aperture plate is arranged between the filter plate and the terminating multi-aperture plate. The multi-beam generation unit may further comprise a third multi-aperture plate or first multi-stigmator plate with a plurality of fourth apertures, each comprising a second plurality individually addressable multi-pole electrodes for forming an electrostatic multi-pole element arranged in the circumference of the plurality of fourth apertures. Each of the second individually addressable multi-pole electrodes is connected to the control unit, configured for additionally individually deflecting, focusing, or correcting an aberration of each of the plurality of primary charged particle beamlets. Thereby, an even large range of focus change is achieved and a direction of a primary charged particle beamlet can be adjusted before the primary charged particle beamlet enters its corresponding terminating aperture.

The multi-beam generation unit can further comprise a fourth multi-aperture plate or second multi-stigmator plate with a plurality of fourth apertures, each comprising a plurality individually addressable multi-pole electrodes for forming an electrostatic multi-pole element arranged in the circumference of the plurality of fourth apertures, each of the individually addressable electrodes being connected to the control unit configured for individually deflecting, focusing or correcting of an aberration of each of the plurality of primary charged particle beamlets. Thereby, a still even larger range of focus change can be achieved.

The multi-beam generation unit can further be comprising a further multi-aperture plate formed as an electrostatic lens array, with a plurality of apertures comprising a plurality of second cylinder electrodes, each being individually connected to the control unit configured for forming during use a plurality of electrostatic lens fields. Thereby, an even larger range of focus change can be achieved. The electrostatic lens array may be formed as a lens electrode plate made of a single electrode layer. In another form, the electrostatic lens array is a two-layer lens-let electrode plate with a lens electrode layer and a ground electrode layer.

In an example, the condenser electrode is formed as a segmented electrode, comprising a plurality of at least four electrode segments, and the control unit is configured to provide during us an asymmetric voltage distribution to the plurality of at least four electrode segments. Thereby the focusing of the plurality of primary charged particle beamlets is facilitated in the curved intermediate image surface with the tilt component.

In an example, the condenser electrode and the terminating multi-aperture plate are arranged at an angle f with respect to each other. Thereby the focusing of the plurality of primary charged particle beamlets is facilitated in the curved intermediate image surface with the tilt component. To adjust the angle f, either the condenser electrode or the stack of multi-aperture plates comprising the terminating multi-aperture plate or both can be mounted on a manipulator configured for tilting or rotating the condenser electrode or the stack of multi-aperture plates or both.

The multi-beam generation unit may comprise a second or further ground electrode plates, each being arranged between a pair of multi-aperture plates of which each comprises an electrode layer and a plurality of individually addressable electrodes. Thereby the individually addressable ring- or multipole electrodes are separated in propagation direction of the primary charged particle beamlets and shielded with respect to each other.

The control unit is configured to provide during use a plurality of individual voltages to each of the plurality of electrodes of the terminating multi-aperture plate, the first multi-stigmator plate and optional the second multi-stigmator plate and/or the electrostatic lens array. The terminating multi-aperture plate, the first multi-stigmator plate and optional the second multi-stigmator plate and/or the electrostatic lens array jointly form an array of individually addressable multi-stage micro lenses with an individually variable focusing range variation DF of at least DF>1 mm, such as at least DF>3 mm, for example DF>5 mm for each individually addressable multi-stage micro lens.

The multi-beam generation unit further comprises a plurality of spacers or support zones for holding the plurality of multi-aperture plates at predetermined distances to each other.

In another aspect, the disclosure provides a multi-aperture plate is formed as an inverted multi aperture plate with electrical wiring connections for the plurality of individually addressable electrodes at the first side opposite to the beam entrance side of the inverted multi-aperture plate. In an example of the multi-beam generation unit according to the first aspect, at least one of the multi-aperture plates is configured as an inverted multi-aperture plate. The at least one inverted multi-aperture plate further comprises a plurality of through connections for electrically connecting the plurality of individually addressable electrodes via the electrical wiring connections at the lower or bottom side of the inverted multi-aperture plate with contact pins arranged at the upper or the beam entrance side of the inverted multi-aperture plate. With the inverted arrangement it is generally possible to improve the electrical isolation and shielding of the electrical wiring connections, for example from primary charged particles, scattered charged particles, secondary charged particles or X-rays generated by charged particles of any kind. Therefore, the individually addressable electrodes can be operated with higher accuracy. With the wiring connections downstream of an electrode layer of an aperture plate, the impact of a leakage of an electrical field from the wiring connections is reduced and it is possible to provide a larger voltage to each of the corresponding individually addressable electrodes and thereby further increase the focusing power.

In an example, the terminating multi-aperture plate of the multi-beam generation unit further comprises a conductive shielding layer with the plurality of apertures. The conductive shielding layer is electrically isolated from the first plurality of individually addressable electrodes and the conductive shielding layer is arranged at the bottom side of the terminating multi-aperture plate between the individually addressable electrodes and the condenser lens. Thereby, a penetration or disturbance of the plurality of electrostatic micro-lens fields is effectively reduced.

In practical examples the first apertures of the filter plate have a first, smallest diameter D1, and the terminating apertures have a terminating, larger diameter DT. The terminating diameter DT is typically in a range between 1.6×D1<=DT<=2.4×D1. The second apertures of the ground electrode plate have a second diameter D2. Typically, D2 is selected between D1 and DT, D1<D2<DT, for example 1.4×D1<=D2<=0.75×DT. The third or further apertures of the first or second multi-stigmator plate or the electrostatic lens array have a diameter D3. Typically, D3 is selected between D2 and DT, such that D1<D2<D3<DT, for example 1.4×D1<=D2<=0.9×D3<=0.8×DT.

According to a second aspect, the disclosure provides a multi-aperture plate of improved performance is provided. The improved multi-aperture plate comprises a plurality of apertures with a plurality of isolated and individually addressable electrodes in an isolated electrode layer. Each of the plurality of electrodes is arranged in the circumference of one of the apertures. The improved multi-aperture plate further comprises a first conductive shielding layer on a first side of the multi-aperture plate with a first thickness T1 of about T1<=1 μm and a layer of a plurality of electrical wiring connections of a third thickness T3<=1 μm. A first planarized isolating layer of a second thickness T2 is arranged between a first conductive shielding layer and the layer of electrical wiring connections. A third planarized isolation layer is formed between the layer of electrical wiring connections and the isolated electrode layer. The third planarized isolation layer has a fourth thickness T4. The third planarized isolation layer is provided with wiring contacts formed between each of a wiring connection and an electrode. The first and the third planarized isolation layers are made of Silicon Dioxide and are levelled down to the second and fourth thickness T2 and T4, each below 3 μm, for example with T2<=T4<=2.5 μm. Each of the second and fourth thickness T2 and T4 can be below or equal to 2 μm. In an example, each of the wiring contacts is placed at an outer edge of each individually addressable electrode with a distance h to the inner sidewall of an aperture. The distance h is larger than h>6 μm, such as h>8 μm, for example h>=10 μm.

The multi-aperture plate further comprises a second conductive shielding layer on a second side of the multi-aperture plate with a sixth thickness T6<=1 μm and a third planarized isolation layer formed between the second conductive shielding layer and the electrode layer, having a fifth thickness T5<=2.5 μm. With the reduced thicknesses of the planarized isolation layers, a disturbance of the electrical fields in vicinity of the multi-aperture plate is reduced and photolithographic processing can be achieved with higher accuracy. Therefore, for example the wiring contacts can be formed with higher precision. With the large distance h of the wiring contacts, a leakage of an electrical field generated from the wiring contacts or electrical wiring connections is further reduced. With the shielding layers provided on both sides and connected to ground level, a penetration of an electrical field into or out of the multi-aperture plate is effectively reduced. In an example, at least one of the first or second conductive shielding layers have a plurality of plunging extensions into each of the plurality of apertures, forming a gap of width g to the electrodes with g<4 μm, such as g<=2 μm. With this small gap, a penetration of an electrical field into or out of the multi-aperture plate is even more effectively reduced. In an example, the multi-aperture plate further comprises a shielding electrode between the plurality of individually addressable electrodes. The shielding electrode is connected to ground level (0V). Thereby, the individually addressable electrodes are effectively shielded from each other.

The multi-aperture plate can be one of a plurality of at least two multi-aperture plates of a multi-beam generation unit configured for generating and focusing during use a plurality of primary charged particle beamlets. In a first example, the improved multi-aperture plate is the terminating multi-aperture plate with a plurality of terminating apertures of the multi-beam generation unit, wherein each of the plurality of primary charged particle beamlets exits the multi-beam generation unit at one of a plurality of terminating apertures. A condenser lens is arranged after the improved multi-aperture plate being the terminating multi-aperture plate of the multi-beam generation unit. The condenser lens is configured for generating during use a plurality of electrostatic micro-lens fields, which are penetrating into the plurality of terminating apertures.

In an example, the improved multi-aperture plate is arranged in an inverted configuration with a plurality of wiring connections at a first side of the multi-aperture plate and a plurality of contact pins at a second side opposite to the first side of the multi-aperture plate, further comprising a plurality of through connections for connecting the plurality of wiring connections at the first side with the contact pins at the second side.

In third aspect, the disclosure provides a terminating multi-aperture plate. The terminating multi-aperture plate comprises a plurality of terminating apertures, configured for forming during use a plurality of electrostatic micro-lens fields, which are penetrating into the plurality of terminating apertures. In the circumference of the terminating apertures, a plurality individually addressable electrodes are arranged. The plurality individually addressable electrodes is configured to be individually connected to a control unit and being configured to individually influence during use the penetration depth and/or shape of each of a plurality of electrostatic micro-lens fields. The terminating multi-aperture plate further comprises a first conductive shielding layer at the terminating or beam exiting side of the terminating multi-aperture plate, connected to ground level (0V). Thereby the plurality of electrostatic micro-lens fields are shielded and prevented from penetrating into the terminating multi-aperture plate and penetrate only into the terminating apertures. The terminating multi-aperture plate further comprises a shielding electrode between the plurality of individually addressable electrodes, connected to ground level (0V) for shielding the plurality of individually addressable electrodes from each other. The terminating multi-aperture plate further comprises a plurality of isolated wiring connections for providing a plurality of individual voltages to the plurality of individually addressable electrodes. The plurality of wiring connections is connected to a control unit.

In an example, the plurality of wiring connections is arranged at a first side of the terminating multi-aperture plate, being isolated from the conductive shielding layer, and the terminating multi-aperture plate further comprises a plurality of through connections connected to the plurality of wiring connections. The plurality of through connections is connected to the control unit.

The terminating multi-aperture plate further comprises a second conductive shielding layer on an upper side of the terminating multi-aperture plate, wherein the upper side is the side where a plurality of charged particle beamlets enters the terminating multi-aperture plate. The terminating multi-aperture plate further comprises a plurality of planarized isolating layers and a layer of a plurality of electrical wiring connections in between two of the planarized isolating layers, an electrode layer, comprising the plurality individually addressable electrodes. Each of the electrode layer, the layer of electrical wiring connections and the first or second conductive shielding layer is isolated from an adjacent layer by one of the planarized isolating layers. Each of the planarized isolation layers are made of Silicon Dioxide and are levelled down to a thickness T below T<3 μm, such as below T<=2.5 μm, for example down to T<=2 μm. By comparison, the electrode layer has typically a thickness of between 50 μm and 100 μm.

In a fourth aspect, the disclosure provides an inverted multi-aperture plate. The inverted multi-aperture plate comprises a plurality of apertures with a plurality of isolated and individually addressable electrodes in an isolated electrode layer. Each one of the plurality of electrodes is arranged in the circumference of one aperture. The inverted multi-aperture plate further comprises a first conductive shielding layer on a first side of the multi-aperture plate with a first thickness T1<=1 μm; a first planarized isolating layer of a second thickness T2<=2.5 μm; at least a layer of a plurality of electrical wiring connections of a third thickness T3<=1 μm; a second planarized isolation layer between the electrode layer and the at least first layer of electrical wiring connections, the second planarized isolation layer having a fourth thickness T4<=2.5 μm. The second planarized isolation layer is photolithographically configured with through wiring contacts formed between the each of a wiring connection and an electrode.

The inverted multi-aperture plate further comprises a plurality of through connections and contact pins for contacting with the control unit at a second, opposite side of the electrode layer. The plurality of electrical wiring connections is arranged on a first side of the first isolated electrode layer, and the through connections enable an electrical contact from the first side through the first isolated electrode layer to the second side. In an example, each of the wiring contacts is placed at an outer edge of each individually addressable electrode, with a distance h to the inner sidewall of an aperture, wherein h can be larger than h>6 μm, such as h>10 μm, for example h=12 μm. The inverted multi-aperture plate further comprises a second conductive shielding layer on the second side of the multi-aperture plate with a sixth thickness T6<=1 μm and a third planarized isolation layer formed between the second conductive shielding layer and the electrode layer opposite to the second planarized isolation layer. The third planarized isolation layer has a fifth thickness of T5<=2.5 μm. The second conductive shielding layer comprises apertures for isolating the contact pins from the second conductive shielding layer. In an example, at least one of the first or second conductive shielding layer have a plurality of plunging extensions into each of the plurality of apertures, forming a gap of width g to the electrodes with g<4 μm, such as g<=2 μm. The inverted multi-aperture plate is further provided a shielding electrode between the plurality of individually addressable electrodes, connected to ground level (0V) for shielding the plurality of individually addressable electrodes from each other.

In a fifth aspect, the disclosure provides a method of individually changing the focus distance of each of a plurality of primary charged particle beam spots by a large range. The method comprises providing a plurality of individually addressable terminating electrodes at each of a plurality of terminating apertures of a terminating multi-aperture plate. In a next step, the method comprises providing a condenser lens electrode adjacent to the terminating multi-aperture plate and downstream of a propagation direction of a plurality of primary charged particle beamlets. In a next step, the method comprises providing by a control unit at least a first voltage to the condenser lens electrode to generate a plurality of electrostatic micro-lens fields, which are penetrating the plurality of terminating apertures. In a next step of the method, a plurality of individual voltages is provided to each of the plurality of individually addressable electrodes. The plurality of individual voltages of the individually addressable terminating electrodes is further controlled to influence the penetration depth of each of the plurality of electrostatic micro-lens fields, thereby independently adjusting an axial focus position of each of the plurality of primary charge particle beamlets on a curved intermediate image surface with a large range of for example DF>1 mm, such as DF>3 mm, for example DF>5 mm. In an example, the plurality of individually addressable electrodes are formed as a plurality multi-pole electrodes and the method further comprises the step of individually controlling the plurality of individual voltages to each of the multi-pole electrodes to influence the shape and/or lateral position of each of the electrostatic micro-lens fields. Thereby, a lateral focus position and shape of each of the plurality of primary charge particle beamlets is independently and individually adjusted on the curved intermediate image surface. The step of individually controlling the plurality of individual voltages can be configured to adjusting the focus position of each of the plurality of primary charge particle beamlets on the curved intermediate image surface with a tilt component.

The method can further comprise the step of providing a first multi-stigmator plate with a plurality of apertures and a plurality of individually addressable multi-pole electrodes and the step of providing—by the control unit—a plurality of individual voltages to each of the plurality of individually addressable multi-pole electrodes. The method according to this example further comprises the step of individually controlling the plurality of individual voltages of the multi-pole electrodes. Thereby the shape and/or lateral position of each of the plurality of primary charge particle beamlets is influenced before passing the plurality of terminating apertures of the terminating multi-aperture plate.

The method can further comprise the step of providing a second multi-stigmator plate with a plurality of apertures and a plurality of individually addressable multi-pole electrodes and the step of providing—by the control unit—a plurality of individual voltages to each of the plurality of individually addressable multi-pole electrodes. The method according to this example further comprises the step of individually controlling the plurality of individual voltages of the multi-pole electrodes. Thereby, the shape and/or lateral position and/or direction of each of the plurality of primary charge particle beamlets is influenced before passing the plurality of terminating apertures of the terminating multi-aperture plate.

The method can further comprise the step of providing a lens array with a plurality of apertures and a plurality of individually addressable ring electrodes and the step of providing—by the control unit—a plurality of individual voltages to each of the plurality of individually addressable ring electrodes. With the individual control of the plurality of individual voltages of the ring electrodes, the focus position of each of the plurality of primary charge particle beamlets is influenced before passing the plurality of terminating apertures of the terminating multi-aperture plate. Thereby, a focusing is facilitated by the lens array and a larger range DF of focus adjustment with DF>1 mm, such as with DF>3 mm, for example DF>5 mm, is achieved.

According to a further example, the method further comprises the step of individually controlling the plurality of individual voltages of the individually addressable terminating electrodes, of any of the multi-pole electrodes, and/or of the ring electrodes. With this method, the axial and lateral focus position, the shape, and the propagation direction of each of the plurality of primary charge particle beamlets is jointly influenced.

According to a further example, the method further comprises the step of controlling a tilt angle or rotation angle of either a condenser lens electrode or the stack of multi-aperture plates of the primary multi-beamlet-forming unit, or both. With this method, the axial focus position of each of the plurality of primary charge particle beamlets is jointly influenced in order to contribute to a tilt component of an intermediate image surface.

According to a sixth aspect, the disclosure provides a multi-beam generation unit with at least one inverted multi aperture plate. The multi-beam generation unit according to the embodiment comprises a filter plate with a plurality of first apertures for generating a plurality of primary charge particle beamlets from an incident, parallel primary charged particle beam. The filter plate connected during use to a ground level. The multi-beam generation unit further comprises a plurality of at least two multi-aperture plates, each multi aperture plate comprises an electrode layer and a plurality of contact pins arranged at a first side of the electrode layer. The plurality of at least two multi-aperture plates comprises a terminating multi-aperture plate. Each multi-aperture plate further comprises at least a layer of a plurality of electrical wiring connections. At least one of the multi-aperture plates is configured as an inverted multi-aperture plate with the layer of a plurality of electrical wiring connections arranged at the second side of the electrode layer of the inverted multi-aperture plate. The second side is opposite to the first side, where the contact pins are arranged. Thereby, each multi-aperture plate of the multi-beam generation unit can be electrically contacted at the same, first side, irrespective of the position of the layer of the plurality of electrical wiring connections of the inverted multi-aperture plate. The inverted multi-aperture plate further comprises a plurality of through connections for electrically connecting the plurality of contact pins with the plurality of electrical wiring connections. The terminating multi-aperture plate comprises an electrode layer with a plurality of individually addressable electrodes, a layer of a plurality of electrical wiring connections and a plurality of contact pins arranged at a first side of the electrode layer. In an example, the layer of the plurality of electrical wiring connections of the terminating multi-aperture plate is arranged at the second side of the electrode layer of the terminating multi-aperture plate. The first side is the upper or beam entering side, and the second side is the lower or bottom side, where the primary beamlets exit the multi-aperture plate.

The multi-beam generation unit further comprises a control unit. The control unit configured to provide a plurality of individual voltages to the each of the plurality of contact pins of each of the multi-aperture plate and/or the terminating multi-aperture plate from the same first side.

The multi-beam generation unit according to the sixth embodiment further comprises a condenser lens with a condenser electrode with a single aperture configured for transmitting during use the plurality of primary charged particle beamlets. The condenser electrode is configured for generating during use electrostatic micro-lens fields, which are penetrating into each of the plurality of terminating apertures. The control unit is configured to individually control the condenser electrode and each of the plurality of individually addressable electrodes of the terminating multi-aperture plate. Thereby, the penetration depth and/or shape of each of the plurality of electrostatic micro-lens fields is influenced and a lateral and axial focus position of each of a plurality of primary charge particle beamlets is facilitated on a curved intermediate image surface.

In a seventh aspect, the disclosure provides a method of fabricating a multi-aperture plate. The method comprises the step of forming a plurality of electrodes in an electrode layer. The method further comprises the step of forming a first isolating layer on a first side of the electrode layer, the first isolating layer being formed of an isolating material such as Silicon dioxide (SiO2). The method further comprises the step of polishing the first isolating layer to form a first, levelled isolating layer with a thickness below 2.5 μm. The method further comprises the step of forming and lithographically processing a layer of electrical wiring connections on the first, levelled isolating layer. The method further comprises the step of forming a second isolating layer on the layer of electrical wiring connections, the second isolating layer being formed of an isolating material such as Silicon dioxide (SiO2). The method further comprises the step of polishing the second isolating layer to form a second, levelled isolating layer with a thickness below 2.5 μm. The method further comprises the step of forming a first conductive shielding layer on the second, levelled isolating layer.

In an example, the method further comprises the step of forming a plurality of through connections through the electrode layer and the step of forming a first isolating layer on a second side of the electrode layer, the second side being opposite to the first side; and the step of polishing the first isolating layer on the second side to form a first, levelled isolating layer with a thickness below 2.5 μm. The method further comprises the step of forming a second conductive shielding layer on the first, levelled isolating layer on the second side and the step of connecting each of the through connections on the first side with one of the electrical wiring connections and connecting each of the through connections on the second side with a contact pin.

In an example, the method further comprises the step of forming a stress reduction layer on the second, levelled isolating layer on the first side, the stress reduction layer being formed of Silicon Nitride (SiOX). The method further comprises the step of forming a further isolating layer on the stress reduction layer and polishing the further isolating layer to level the further, levelled isolating layer down to a thickness of below 2.5 μm. The first conductive shielding layer according to this example is then formed on the further, levelled isolating layer.

In an embodiment, the plurality of transmitting beamlets propagates through a plurality of apertures of a plurality of multi-aperture plates in a first direction, high voltage supply wiring connections are provided to first electrodes in at least one of the multi-aperture plates from a second direction perpendicular to the first direction, and low voltage supply wiring connections are provided to second electrodes in at least one of the multi-aperture plates from a third direction perpendicular to the first and second direction.

By the embodiments of the disclosure, a multi-beam generation unit of large range of focusing power is given. A multi-beam generation unit according to the embodiments comprises a filter plate with a plurality of first apertures for generating a plurality of primary charge particle beamlets from an incident, parallel primary charged particle beam. A multi-beam generation unit further comprises at least a first multi-aperture plate with an electrode layer and a terminating multi-aperture plate with a plurality of terminating apertures. A multi-beam generation unit further comprises a condenser lens with a condenser electrode and a control unit configured to provide a plurality of individual voltages to the at least a first multi-aperture plate, the terminating multi-aperture plate and the condenser electrode. In an example, the control unit is further configured to adjust an angle between the terminating multi-aperture plate and the condenser lens with the condenser electrode. A multi-beam generation unit according to the embodiments is configured for individually adjusting each of a axial focus position of each of the plurality of primary charged particle beamlets with a focus range DF of more than DF>1 mm, such as DF>3 mm, including DF>5 mm, for example DF>=6 mm. In an example, a multi-beam generation unit is further configured for focusing each of the plurality of primary charged particle beamlets on a curved intermediate surface, wherein the curved intermediate surface has a tilt component. With the improved multi-aperture plates according to some of the embodiments, the multi-beam generation unit is further configured for individually adjusting each of a lateral focus position of each of the plurality of primary charged particle beamlets on the curved surface with an accuracy below 20 nm, such as below 15 nm, for example below 10 nm. The multi-beam generation unit is therefore configured for individually adjusting a shape or aberration of each of the plurality of primary charged particle beamlets to form a plurality of stigmatic focus points (on the curved intermediate surface with high accuracy. With the improvements to the multi-aperture plates provided by some of the embodiments, a higher beamlet quality is achieved and the focus points at the intermediate image plane are formed with lower aberrations. The plurality of focus points is thus formed with higher precision and less deviation from the image plane of a multi-beam charged particle system. The disclosure allows therefore a wafer inspection with higher precision, especially with a better compensation or a field curvature error of the multi-beam charged particle system and consequently with a lower variation of focus spot sizes of the focus spots on a wafer surface arranged in the image plane. With the increased focusing range of the individually addressable electrostatic lens field of the multi-beam generating unit, the tilt component of the field curvature error of the multi-beam charged particle system can be adapted to the rotation of the raster of primary charged particle beamlets by an objective lens of the multi-beam charged particle system. Even when a imaging setting of the multi-beam charged particle system is changed, and a rotation of the raster of primary charged particle beamlets is changed, or an amount of field curvature error is changed by for example changing the voltage supplied to the wafer by a sample voltage supply, the change of field curvature error can easily compensated by the multi-beam generating with large, individual focus changing power DF of exceeding 1 μm or 3 μm, or DF can even by larger by the combinations of multi-aperture plates, by using of multi-aperture plates with better shielding and more precise fabrication of the wiring connections, or by combinations of both, as described above in the embodiments.

It will be understood that the disclosure is not limited to the embodiments and examples but comprises also combinations and variations of the embodiments and examples.

### BRIEF DESCRIPTION OF THE DRAWINGS

Embodiments of the present disclosure will be explained in more detail with reference to drawings.

FIG. 1 is a schematic sectional view of a multi-beam charged particle system for wafer inspection.

FIG. 2 illustrates some aspects of a multi-beam raster unit.

FIG. 3 shows a first example of a multi-beam generating unit.

FIG. 4 shows some details of a two-layer lens-let plate.

FIG. 5 shows second example of a multi-beam generating unit with an inverted two-layer lens-let plate.

FIG. 6 shows a third example of a multi-beam generating unit with changed order of elements.

FIG. 7 shows a fourth example of a multi-beam generating unit with a terminating multi-aperture plate, formed as a lens-let plate.

FIGS. 8a,b illustrate the function of the terminating multi-aperture plate at two examples.

FIG. 9 shows a fifth example of a multi-beam generating unit.

FIG. 10 shows a sixth, further simplified example of a multi-beam generating unit.

FIG. 11 shows a seventh example of a multi-beam generating unit with increased correction capability.

FIG. 12 shows an eighth example of a multi-beam generating unit with increased correction capability.

FIG. 13 shows a ninth example of a multi-beam generating unit with increased correction capability.

FIG. 14 shows a tenth example of a multi-beam generating unit with a condenser lens with ring shaped multipole electrode segments.

FIG. 15a illustrates a front view of a multi-stigmator plate.

FIG. 15b illustrates a ring-shaped multipole electrode segments of condenser lens.

FIGS. 16a,b illustrate the fabrication steps for fabricating a lens electrode layer with improved performance.

FIG. 17 illustrates the fabrication steps for fabricating a lens electrode layer with through connections and through holes.

FIG. 18 shows an example of a stacking of a plurality of multi-aperture plates, including inverted multi-aperture plates and wiring connections from the top or upper side (in negative z-direction).

FIG. 19 shows a multi-beam raster unit according to an embodiment with signal and voltage supply wiring lines from orthogonal directions.

FIG. 20 shows a multi-beam raster unit according to an embodiment with a tilt angle between terminating multi aperture plate and condenser lens electrode.

### DESCRIPTION OF EXEMPLARY EMBODIMENTS

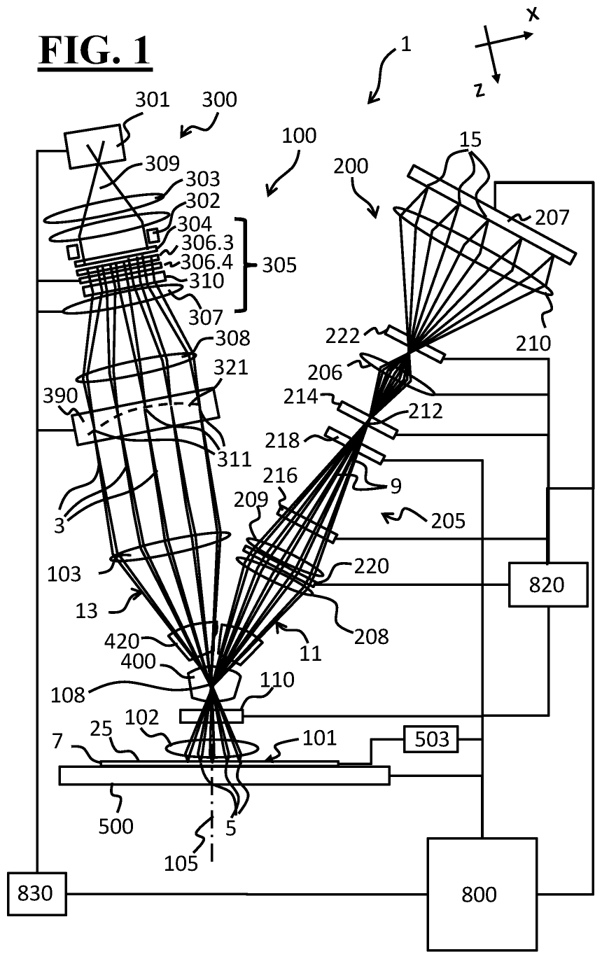

In the exemplary embodiments of the disclosure described below, components similar in function and structure are indicated as far as possible by similar or identical reference numerals. The multi-beam raster units of the examples are described in the illumination beam path with charged particles propagating in positive z-direction with the z-direction pointing downwards. However, multi-beam raster units can also be applied in the imaging beam path, with secondary charged particle beamlets propagating in negative z-direction in the coordinate system of FIG. 1. Still, the sequence of multi-aperture plates is arranged in sequence in the propagating direction of the transmitting charged particle beam or beamlets. With beam entrance side or upper side is understood the first surface or side of an element in the direction of the transmitting charged particle beam or beamlets, with bottom side or beam exiting side is understood the last surface or side of an element in the direction of the transmitting charged particle beam or beamlets.

Some array elements, for example the plurality of primary charged particle beamlets, are identified by the reference number. Depending on the context, the same reference number may also identify a single element out or the array elements. Each primary charged particle beamlet (3.1, 3.2, 3.3, 3.4) is one of the plurality of primary charged particle beamlets (3). It will be clear from the context, whether a single element of an array of elements is meant.

The schematic representation of FIG. 1 illustrates basic features and functions of a multi-beam charged-particle microscopy system 1 according to the embodiments of the disclosure. It is to be noted that the symbols used in the figure have been chosen to symbolize their respective functionality. The type of system shown is that of a multi-beam scanning electron microscope (MSEM or Multi-SEM) using a plurality of primary electron beamlets 3 for generating a plurality of primary charged particle beam spots 5 on a surface 25 of an object 7, such as a wafer located with a top surface 25 in an object plane 101 of an objective lens 102. For simplicity, only five primary charged particle beamlets 3 and five primary charged particle beam spots 5 are shown. The features and functions of multi-beamlet charged-particle microscopy system 1 can be implemented using electrons or other types of primary charged particles such as ions and in particular Helium ions. Further details of the microscope system 1 are provided in International Patent application PCT/EP2021/066255, filed on Jun. 16, 2021, which is hereby fully incorporated by reference.

The microscopy system 1 comprises an object irradiation unit 100 and a detection unit 200 and a beam splitter unit 400 for separating the secondary charged-particle beam path 11 from the primary charged-particle beam path 13. Object irradiation unit 100 comprises a charged-particle multi-beam generator 300 for generating the plurality of primary charged-particle beamlets 3 and is adapted to focus the plurality of primary charged-particle beamlets 3 in the object plane 101, in which the surface 25 of a wafer 7 is positioned by a sample stage 500.

The primary beam generator 300 produces a plurality of primary charged particle beamlet spots 311 in an intermediate image surface 321, which is typically a spherically curved surface. According to the embodiments of the disclosure, the intermediate image plane 321 is further tilted to compensate a tilt induced by the off-axis symmetry of the object irradiation unit 100. The positions of the plurality of focus points (311) of the plurality of primary charged particle beamlets (3) is adjusted in the intermediate image surface (321) by a multi-beam generating unit (305) to pre-compensate field curvature and image plane tilt of optical elements of the object irradiation unit (100) downstream of the multi-beam generating unit 305. The orientation of the image plane tilt 321 and the amount of field curvature is adjusted according to the driving parameters of the object irradiation unit 100, for example on the focusing power of the objective lens 102 or the electrostatic field generated between the objective lens 102 and the wafer surface 25 by the voltage supplied by the sample voltage supply (503), which both are the main sources for field curvature and rotation of the tilted image plane. More details about the intermediate image plane curvature and tilt are described in German patent DE 102021200799 B3, which is incorporated herein by reference.

The primary beamlet generator 300 comprises a source 301 of primary charged particles, for example electrons. The primary charged particle source 301 emits a diverging primary charged particle beam, which is collimated by at least one collimating lens 303 to form a collimated or parallel primary charged particle beam 309. The collimating lens 303 is usually consisting of one or more electrostatic or magnetic lenses, or by a combination of electrostatic and magnetic lenses. The primary beamlet generator 300 further comprises a deflector 302 for adjusting the angle of the collimated or parallel primary charged particle beam 309. The collimated primary charged particle beam 309 is incident on the primary multi-beam forming unit 305. The multi-beam forming unit 305 basically comprises a first multi-aperture plate or filter plate 304 illuminated by the collimated primary charged particle beam 309. The first multi-aperture plate or filter plate 304 comprises a plurality of apertures in a raster configuration for generation of the plurality of primary charged particle beamlets 3, which are generated by transmission of the collimated primary charged particle beam 309 through the plurality of apertures. The multi-beamlet forming unit 305 comprises at least two of further multi-aperture plates 306.3-306.4, which are located, with respect to the direction of movement of the electrons in beam 309, downstream of the first multi-aperture or filter plate 304. For example, a second multi-aperture plate 306.3 has the function of a micro lens array, comprising a plurality of ring electrodes, each ring electrode set to an individually defined potential so that the focus positions of the plurality of primary beamlets 3 are independently adjusted in the intermediate image surface 321. A third multi-aperture plate 306.4 comprises for example four or eight of electrostatic elements for each of the plurality of apertures, for example to deflect each of the plurality of beamlets individually. The multi-beamlet forming unit 305 according to some embodiments is configured with a terminating multi-aperture plate (3.10). The multi-beamlet forming unit 305 is further configured with an adjacent electrostatic field lenses 307, which is in some examples combined in the multi-beamlet forming unit 305. More details of the multi-beamlet forming unit 305 are described below. Together with an optional second field lens 308, the plurality of primary charged particle beamlets 3 is focused in or in proximity of the intermediate image surface 321.

In or in proximity of the intermediate image surface 321, a beam steering multi aperture plate 390 can be arranged with a plurality of apertures with electrostatic elements, for example deflectors, to manipulate individually the propagation direction of each of the plurality of charged particle beamlets 3. The apertures of the beam steering multi aperture plate 390 are configured with larger diameter to allow the passage of the plurality of primary charged particle beamlets 3 even in case the focus spots 311 of the primary charged particle beamlets 3 are located on the curved intermediate image surface 321. The primary charged-particle source 301, each of the active multi-aperture plates 306.3 . . . 306.4, and the beam steering multi aperture plate 390 are controlled by primary beamlet control module 830, which is connected to control unit 800.

The plurality of focus points of primary charged particle beamlets 3 passing the intermediate image surface 321 is imaged by field lens group 103 and objective lens 102 into the image plane 101, in which the surface 25 of the wafer 7 is positioned. A decelerating electrostatic field is generated between the objective lens 102 and the wafer surface by application of a voltage to the wafer by the sample voltage supply (503). The object irradiation system 100 further comprises a collective multi-beam raster scanner 110 in proximity of a first beam cross over 108 by which the plurality of charged particle beamlets 3 can be deflected in a direction perpendicular to the propagation direction of the charged particle beamlets. The propagation direction of the primary beamlets throughout the examples is in positive z-direction. Objective lens 102 and collective multi-beam raster scanner 110 are centered at an optical axis 105 of the multi-beam charged-particle system 1, which is perpendicular to wafer surface 25. The plurality of primary charged particle beamlets 3, forming the plurality of beam spots 5 arranged in a raster configuration, is scanned synchronously over the wafer surface 25. In an example, the raster configuration of the focus spots 5 of the plurality of N primary charged particle 3 is a hexagonal raster of about one hundred or more primary charged particle beamlets 3, for example N=91, N=100, or N approximately 300 or more beamlets. The primary beam spots 5 have a distance about 6 μm to 15 μm and a diameter of below 5 nm, for example 3 nm, 2 nm or even below. In an example, the beam spot size is about 1.5 nm, and the distance between two adjacent beam spots is 8 μm. At each scan position of each of the plurality of primary beam spots 5, a plurality of secondary electrons is generated, respectively, forming the plurality of secondary electron beamlets 9 in the same raster configuration as the primary beam spots 5. The intensity of secondary charged particle beamlets 9 generated at each beam spot 5 depends on the intensity of the impinging primary charged particle beamlet 3, illuminating the corresponding spot 5, the material composition and topography of the object 7 under the beam spot 5, and the charging condition of the sample at the beam spot 5. Secondary charged particle beamlets 9 are accelerated by the electrostatic field generated by the sample charging unit 503 between the sample 7 and the objective lens 102. The plurality of secondary charged particle beamlets 9 are accelerated by the electrostatic field between objective lens 102 and wafer surface 25 and are collected by objective lens 102 and pass the first collective multi-beam raster scanner 110 in opposite direction to the primary beamlets 3. The plurality of secondary beamlets 9 is scanning deflected by the first collective multi-beam raster scanner 110. The plurality of secondary charged particle beamlets 9 is then guided by beam splitter unit 400 to follow the secondary beam path 11 of the detection unit 200. The plurality of secondary electron beamlets 9 is travelling in opposite direction from the primary charged particle beamlets 3, and the beam splitter unit 400 is configured to separate the secondary beam path 11 from the primary beam path 13 usually via magnetic fields or a combination of magnetic and electrostatic fields. Optionally, additional magnetic correction elements 420 are present in the primary or in the secondary beam paths.

Detection unit 200 images the secondary electron beamlets 9 onto the image sensor 207 to form there a plurality of secondary charged particle image spots 15. The detector or image sensor 207 comprises a plurality of detector pixels or individual detectors. For each of the plurality of secondary charged particle beam spots 15, the intensity is detected separately, and the material composition of the wafer surface 25 is detected with high resolution for a large image patch of the wafer with high throughput. For example, with a raster of 10×10 beamlets with 8 μm pitch, an image patch of approximately 88 μm×88 μm is generated with one image scan with collective multi-beam raster scanner 110, with an image resolution of for example 2 nm or below. The image patch is sampled with half of the beam spot size, thus with a pixel number of 8000 pixels per image line for each beamlet, such that the image patch generated by 100 beamlets comprises 6.4 gigapixel. The digital image data is collected by control unit 800. Details of the digital image data collection and processing, using for example parallel processing, are described in international patent application WO 2020151904 A2 and in U.S. Pat. No. 9,536,702, which are hereby incorporated by reference.

Projection system 205 further comprises at least a second collective raster scanner 222, which is connected to scanning and imaging control unit 820. Control units 800 and imaging control unit 820 are configured to compensate a residual difference in position of the plurality of focus points 15 of the plurality of secondary electron beamlets 9, such that the positions of the plurality secondary electron focus spots 15 are kept constant at image sensor 207.

The projection system 205 of detection unit 200 comprises further electrostatic or magnetic lenses 208, 209, 210 and a second cross over 212 of the plurality of secondary electron beamlets 9, in which an aperture 214 is located. In an example, the aperture 214 further comprises a detector (not shown), which is connected to imaging control unit 820. Imaging control unit 820 is further connected to at least one electrostatic lens 206 and a third deflection unit 218. The projection system 205 can further comprise at least a first multi-aperture corrector 220, with apertures and electrodes for individual influencing each of the plurality of secondary electron beamlets 9, and an optional further active element 216, connected to control unit 800 or imaging control unit 820.

The image sensor 207 is configured by an array of sensing areas in a pattern compatible to the raster arrangement of the secondary electron beamlets 9 focused by the projecting lens 205 onto the image sensor 207. This enables a detection of each individual secondary electron beamlet independent from the other secondary electron beamlets incident on the image sensor 207. The image sensor 207 illustrated in FIG. 1 can be an electron sensitive detector array such as a CMOS or a CCD sensor. Such an electron sensitive detector array can comprise an electron to photon conversion unit, such as a scintillator element or an array of scintillator elements. In another embodiment, the image sensor 207 can be configured as electron to photon conversion unit or scintillator plate arranged in the focal plane of the plurality of secondary electron particle image spots 15. In this embodiment, the image sensor 207 can further comprise a relay optical system for imaging and guiding the photons generated by the electron to photon conversion unit at the secondary charged particle image spots 15 on dedicated photon detection elements, such as a plurality of photomultipliers or avalanche photodiodes (not shown). Such an image sensor is disclosed in U.S. Pat. No. 9,536,702, which is cited above and incorporated by reference. In an example, the relay optical system further comprises a beam splitter for splitting and guiding the light to a first, slow light detector and a second, fast light detector. The second, fast light detector is configured for example by an array of photodiodes, such as avalanche photodiodes, which are fast enough to resolve the image signal of the plurality of secondary electron beamlets 9 according to the scanning speed of the plurality of primary charged particle beamlets 3. The first, slow light detector can be a CMOS or CCD sensor, providing a high-resolution sensor data signal for monitoring the focus spots 15 or the plurality of secondary electron beamlets 9 and for control of the operation of the multi-beam charged particle microscope 1.

During an acquisition of an image patch by scanning the plurality of primary charged particle beamlets 3, the stage 500 is optionally not moved, and after the acquisition of an image patch, the stage 500 is moved to the next image patch to be acquired. In an alternative implementation, the stage 500 is continuously moved in a second direction while an image is acquired by scanning of the plurality of primary charged particle beamlets 3 with the collective multi-beam raster scanner 110 in a first direction. Stage movement and stage position is monitored and controlled by sensors known in the art, such as Laser interferometers, grating interferometers, confocal micro lens arrays, or similar.

According to an embodiment of the disclosure, a plurality of electrical signals is created and converted in digital image data and processed by control unit 800. During an image scan, the control unit 800 is configured to trigger the image sensor 207 to detect in predetermined time intervals a plurality of timely resolved intensity signals from the plurality of secondary electron beamlets 9, and the digital image of an image patch is accumulated and stitched together from all scan positions of the plurality of primary charged particle beamlets 3.

A multi-beam generating unit 305 is for example explained in US 2019/0259575, and in U.S. Ser. No. 10/741,355 B1, both hereby incorporated by reference. Further details of a multi-beam generating unit 305, which is insensitive to fabrication errors and scattering are disclosed in WO 2021180365 A1, which is hereby incorporated by reference.

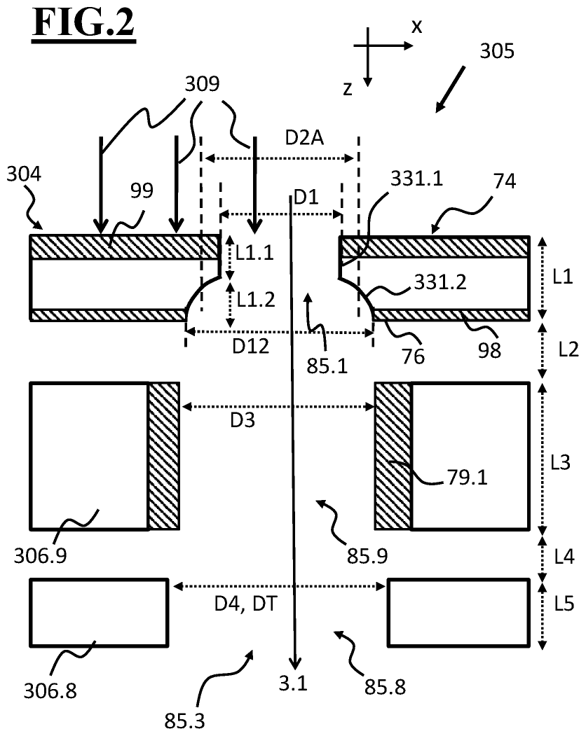

Some aspects of the embodiments of the disclosure are illustrated in FIG. 2. FIG. 2 shows a cross section of a multi-beam generating unit 305. FIG. 2 only shows a part of an inner zones or membranes of the multi-beam generating unit 305. As will be explained in more detail below, a multi-aperture plates further comprises a support zone to support the thin membrane zone and to provide mechanical stability. The multi-beam generating unit 305 comprises a first multi-aperture plate or filter plate 304 with a plurality of apertures 85.1, of which only one aperture 85.1 is shown. At the entrance side 74, each aperture 85.1 has a circular shape with diameter of D1. Parts of the collimated incident electron beam 309 are passing the apertures 85.1 and are forming the plurality of primary charged particle beamlets 3, for example beamlet 3.1. The first multi-aperture plate 304 is covered with a metal layer 99 for stopping and absorbing the impinging electron beam 309 in the circumference of the plurality of apertures 85.1. Metal layer 99 is formed for example by aluminum or gold and connected to a large capacity, for example ground (0V). During use, a large part of the incident electrons from electron beam 309 is absorbed in absorbing layer 99 and an electrical current corresponding to the number of absorbed electrons is generated. For example, with D1=30 μm and with a pitch P1 of the plurality of apertures of 150 μm, about 97% of the incident electrons from the collimated incident electron beam 309 are absorbed and a high current of electrons is generated. Absorbing layer 99 shows therefore during use a fluctuating voltage difference corresponding to the induced current and is therefore not suited to form an electrode for an electrostatic element. The upper segment 331.1 including the metal layer 99 has a thickness of L1.1, wherein 2 μm≤L1.1≤5 μm, providing enough stopping power to the impinging electrons of the charged particle beam 309 and supporting the metal film 99.

The multi-aperture-plate 304 of the example of FIG. 2 further comprises a second segment 331.2 with z-extension L1.2 of about 5 μm. The first multi-aperture plate 304 has a thickness L1 about 7 μm-10 μm. At the entrance surface 74, the aperture 85.1 has a diameter of D1. The second segment 331.2 is configured with inner sidewalls forming concave circular sections in the x-z-plane, with continuously increasing diameter and tangent vectors 103 in x-z-plane are pointing away from the main direction of the passing electron beam 77. The slope at the inner walls of the second segment 101.2 is thus pointing away from the passing electron beam 3.1 and ends with a maximum aperture diameter D12 at the exit or bottom surface 107 of the multi-aperture plate 73.1. The maximum aperture diameter D12 at the exit surface 107 is larger as the aperture diameter D1 of the first segment 101.1.

In an example, the beam exit surface 76 is covered by a conductive layer 98, which is connected to a potential, for example to ground level (0V). The conductive layer with boundary or edge with diameter D12 forms an opposite electrode for the subsequent, second multi-aperture plate or lens-let plate 306.9, which is adjacent to the first multi aperture plate 304. To form, during use, a plurality of electrostatic lens elements, the second multi-aperture plate 306.9 is configured with ring-electrodes 79 around each aperture 85.9, for example electrode 79.1, with diameter D3. Each ring electrode 79 is connected to an individual voltage supply, providing predetermined voltages between 0V and 100V to each of the ring electrodes 79, thereby adjusting the focus position for each of the plurality of primary charged particle beamlets 3, for example beamlet 3.1. The second multi-aperture plate 306.9 has a length L3 about 30 μm-300 μm.

The multi-beam generating unit 305 of FIG. 2 comprises a third multi-aperture plate or ground electrode 306.8 with a plurality of apertures 85.8. Multi-Aperture plate 306.8 is either formed by a conductive material or covered with a conductive layer (not shown) and connected to ground level. Multi-Aperture plate or ground electrode plate 306.8 is thus forming the third electrode of the plurality of electrostatic Einzel-lenses with central electrodes 79 of the second multi-aperture plate 306.9. The thickness of the third multi-aperture plate 306.8 is between 40 μm and 100 μm, for example L5=50 μm. The distances L2 und L4 between the multi-aperture plates 304, 306.9 and 306.8 are in a range of 10 μm to 40 μm each. The distance can be inhomogeneous, for example by a bending of multi-aperture plates or by a thickness distribution of a multi-aperture plate and the distance between two multi-aperture plates can also be less than 10 μm, for example 5 μm. Throughout the examples in FIG. 2 and below, the apertures of lower multi-aperture plates, such as plate 306.9 or plate 306.8 are configured with apertures larger compared to D1, such that D3>D1 and D4>D1. The diameters D3 or D4 can be D3>1.5×D1 and D4>1.5×D1. More examples of the increasing diameters will be shown below.

With the multi-beam generating unit 305 of FIG. 2, a compensation of a field curvature and a compensation of an image plane tilt is only possible with a limited range or stroke. Without the improved design illustrated below, an adjustment of the focusing power by each individual lens-let, formed by the ring electrodes 79.1 is of limited range. Typically, with such an Einzel-lens, a focusing power of less than 1 mm in the intermediate plane 321 can be achieved; typically, the ratio of change of focus position per voltage is below 1 mm/100V, for example 9 μm/1V. For larger focusing stroke, large voltages would have to be provided to the electrodes, which lead to large aberrations and cross talk, for example by induced charging and leakage of electrical fields. The limited focusing range is especially a problem for the high specifications of multi-beam systems 1 for wafer inspection, as well as for multi-beam systems 1 with larger numbers of primary charged particle beamlets and thus larger fields, for example with a plurality of N>200 or N>300 primary charged particle beamlets. In such systems, the curved intermediate image plane 321 with an image plane tilt involves an individual and independent change of focusing power DF for each of the plurality of primary charged particle beamlets (3) with DF>1 mm, such as DF>3 mm, or even with DF>5 mm. For example, the orientation of an image plane tilt and the amount of field curvature depends on a setting of the magneto-optical field lens group (103) and the magneto-optical objective lens (102) of the multi-beam systems 1, and for each different setting of the field lens group (103) and objective lens 102, the focusing power DF for each of the plurality of primary charged particle beamlets (3) is changed independently and individually according to the amount of field curvature and the orientation of the tilt of the image plane.

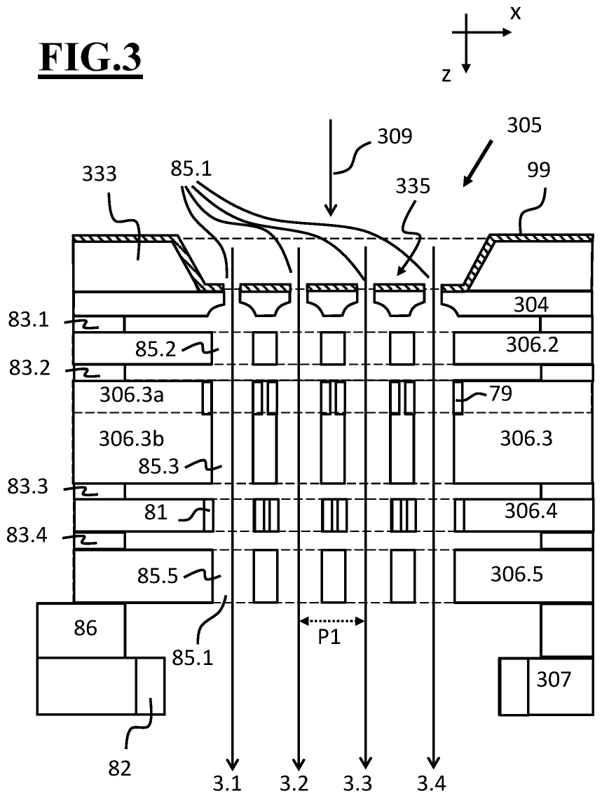

FIG. 3 illustrates a first example of the disclosure. According to FIG. 3, the multi-beam generating unit 305 of the first example comprises in z-direction of the propagating electrons a sequence of five multi-aperture plates 304 and 306.2 to 306.5, and a global condenser lens 307. Each multi aperture plate 304 and 306.2 to 306.5 comprise a plurality of apertures 85.1 to 85.5, spaced at the same lateral distance P1 in each plate and each plate aligned such that a plurality of primary charged particle beamlets 3 is generated and shaped. The plurality of multi-aperture plates 304 and 306.2 to 306.5 and global lens electrode 307 are spaced by spacers 83.1 to 83.4 and spacer 86. The multi-beam generating unit 305 is illustrated in cross section (x,z) with only four apertures 85.1 to 85.5 in each multi-aperture plate shown, with the inner membrane zone 335 and the support zone 333. The first multi-aperture or filter plate 304 has the same function and is similar to the filter plate 304 of FIG. 2, but does not necessarily have a conductive layer 98 at the bottom side 76. The bulk material of the filter plate 304 is made of a conductive material, for example of doped silicon, and is connected to ground level. The second multi aperture plate 306.2 is a ground electrode plate, which is similar to the multi aperture plate 306.8 of FIG. 2. The second multi aperture or ground electrode plate 306.2 is made of conductive material, for example doped silicon, and is connected to ground level (0V).

The third multi-aperture plate 306.3 is a two-layer lens-let plate with a first layer 306.3a comprising a plurality of ring electrodes 79 for the plurality of apertures, each configured to individually change a focus position of a corresponding primary charged particle beamlets, for example the charge particle beamlets 3.1 to 3.4. The second layer 306.3b, downstream of the first layer 306.3a, is isolated from the first layer and made of conductive material such as doped silicon. The second layer 306.3b is connected to ground level (0V). The ground electrode plate 306.2, the first layer 306.3a and the second layer 306.3b form during use a plurality of individually adjustable Einzel lenses for the plurality of primary charged particle beamlets 3. More details of the two-layer lens-let plate 306.3 with larger focusing range DF will be explained below.

The multi-beam generating unit 305 further comprises a fourth multi-aperture of multi-stigmator plate 306.4, which can also serve as a multi-deflector plate. The multi-stigmator-plate 306.4 comprises a plurality of four or more electrodes 81, for example eight electrodes for each of the plurality of apertures 85.4 (not labelled in FIG. 3). During use, different voltages in the range between −20V to +20V can be provided to each of the electrodes, and thereby each beamlet 3.1 to 3.4 can be influenced individually. For example, with an antisymmetric voltage difference, each beamlet 3.1 to 3.4 can be deflected in each direction by up to few μm to pre-compensate a distortion aberration of the illumination unit 100. Typically, a distortion of about +/−10 μm in the intermediate image surface 321 or of about +/−0.5 μm in the image plane 101 can be compensated by voltages of up to +−10V. For example, an astigmatism of each beamlet 3.1 to 3.4 can be compensated. With an offset voltage, each multi-pole element can in addition perform as an Einzel-lens. Each multi-pole element can form an offset of a round lens field together with the second layer 306.3b and the hybrid lens plate 306.5, which are both connected to ground level (0V). Thereby, a focusing range DF is additionally increased.

The fifth multi-aperture plate or hybrid lens plate 306.5 is fabricated from doped silicon and forms a further electrode connected to ground level (0V). In an example, the fifth multi-aperture plate 306.5 can also be covered by a conductive layer, for example by deposition of a metal layer, for example a gold (Au) or composite layer such as AuPd. In the example of FIG. 3, the first condenser lens 307 is connected to the multi-beam forming unit 305. The condenser lens 307 comprises a ring electrode 82, to which a high voltage of −3 kV to −20 kV can be applied, for example−12 kV to −17 kV. The condenser lens 307 forms on the one hand a global electrostatic lens field for a global focusing action on the plurality of primary charged particle beamlets 3, including beamlets 3.1-3.4. The electrostatic lens fields penetrate the apertures of the hybrid lens plate 306.5, for example into each of the apertures 85.5, and an additional electrostatic lens field with focusing power is generated in each aperture of the hybrid lens plate 306.5. The electrostatic lens fields of hybrid lens plate 306.5 of the prior art can however not be individually adjusted, and do not allow a compensation of a variable image plane tilt or a variable amount of field curvature.

With the optional further condenser lens 308, each of the plurality of primary charged particle beamlets 3 including the beamlets 3.1 to 3.4 is focused during use into the curved and tilted intermediate image plane 321 to form focus stigmatically corrected spots.

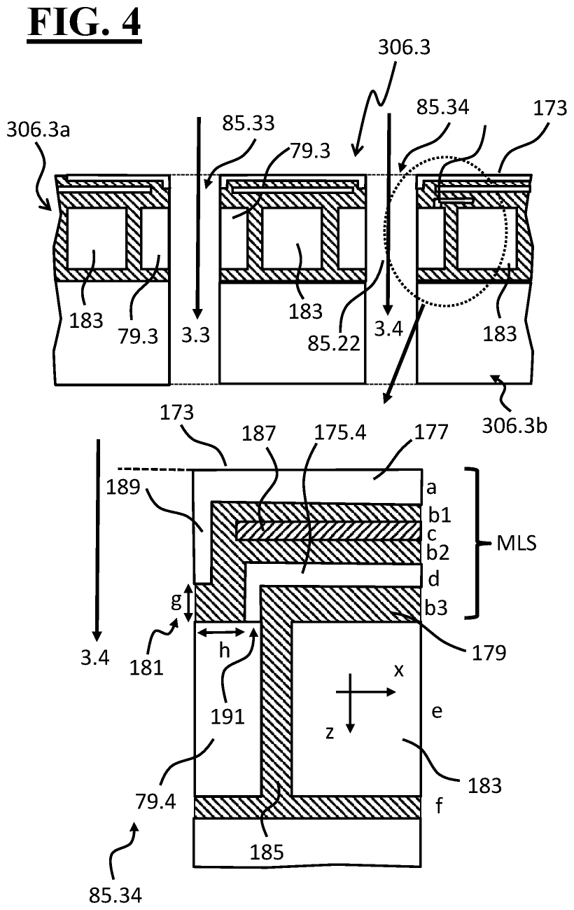

FIG. 4 illustrates the segment 306.3a of the two-layer lens-let plate 306.3 with increased focus range DF. The two-layer lens-let plate 306.3 comprises an inner zone or membrane with a plurality of apertures 85.3 and 85.4 (only two shown) and ring electrodes 79.3 and 79.4 arranged around the apertures 85.33 and 85.34. The apertures are in alignment with the plurality of apertures 85.1 of the filter plate 304 to transmit the charged particle beamlets 3.3 and 3.4. The ring electrodes are isolated via isolation gaps 185 from the bulk silicon or SOI substrate, for example by isolating material silicon dioxide. The bulk silicon or SOI substrate is for example made of doped silicon and acts as shielding electrode 183 set to ground level. Each ring-shaped electrode 79.3, 79.4 is electrically connected to a voltage supply via electrical wiring connections 175, for example wiring connection 175.4, to a voltage support (not shown) of the control unit 830 (see FIG. 1) and isolated by isolation material 179 from the substrate 183. Isolation material is for example silicon oxide, which is either generated by thermal oxidation of the bulk material (doped silicon), or by deposition of silicon oxide, for example from Tetraethyl orthosilicate (TEOS). The isolation material 179 extends above the wiring connection 175.4, such that the wiring 175.4 and the bulk material 183 are completely covered at the upper side. The inner sidewalls of the round electrodes 79 are not covered by isolation material 179. Above the isolation material, a conductive shielding layer 177 is formed, which forms the beam entrance or upper surface 173 of the two-layer lens-let plate 306.3. The conductive layer extends into the apertures with plunging extensions 189 and a small isolation gap 181 of width g is formed between conductive shielding layer 177 and electrode 79.4, thereby conductive layer 177 is isolated from electrode 79.4. Conductive layer 177 is connected to a huge capacity, for example to ground (U=0V). During use, scattered charged particles are thus absorbed by conductive shielding layer 177 and conducted away and disturbing surface charges are avoided. With the conductive layer 177 connected to a large capacity, stable electrostatic elements are generated during use. Thereby, surface charges during use are reduced to less than 10% compared to conventional multi-aperture plates. The gap distance g is below 6 μm, for example below 4 μm, such as even below 2 μm, for example 1 μm. Surface charges in the small isolation gap 181 disappear due to the small distance g of the isolation gap 181. Further, with the improved design, the wiring connection 175.4 is connected to the electrode 79.4 with a large distance h to the cylindrical inner wall of the aperture 85.4, such that a leakage of an electrostatic field induced by the wiring connection through the isolation gap 181 and is minimized. For example, the wiring connection is formed in the proximity of an outer edge of the ring electrode 79.4. With this arrangement, larger voltages, for example voltages of up to 200V, such as voltages between 0V and 500V can be applied to each of the ring electrodes 79. The distance h can be larger than 6 μm, for example 10 μm or 12 μm. By providing conductive shielding layer 177 with an extension plunging into apertures 85 of the lens-let layer 306.3a and forming small gaps 181 of width g to the electrodes 79, and with large distance h to the wiring connections 175, larger voltages exceeding 100V, for example 150V or 200V, or even 500V can be provided and electrostatic lens elements of larger focusing range DF and lower aberrations can be generated during use.

The conductive shielding layer 177 is made of metal, for example Aluminum with a thickness a of about 2 μm and is connected to ground. Wiring connections 175.4 are for example formed by Aluminum, Gold or Copper with a thickness of d=1 μm. Each of the isolation layers of the isolating silicon oxide 179 has a thickness b1, b2 or b3 of 2 μm to 4 μm. To avoid stress induced deformation, an optional further stress compensation layer 187 can be provided. The stress compensation layer 187 can for example be formed by SiNx with a thickness c between 1 μm and 2 μm. The layers 177, 175 and 187 form together with the isolating material 179 a multi-layer stack MLS. Each isolation layer can be planarized and levelled down to a thickness below 2.5 μm, for example by chemical-mechanical polishing (CMP). The levelling enables a more precise lithographic processing of for example the wiring connections 175 or the plunging extensions 189. With a levelling, the stress compensation layer 187 can be omitted, which reduces the overall thickness of the multi-layer stack MLS. The multi-layer stack of an improved multi-aperture plate does not exceed a thickness of 10 μm, such as about 8 μm. Thereby, a planar surface of the conductive shielding layer 177 with less disturbances of the electrostatic lens fields can be fabricated.

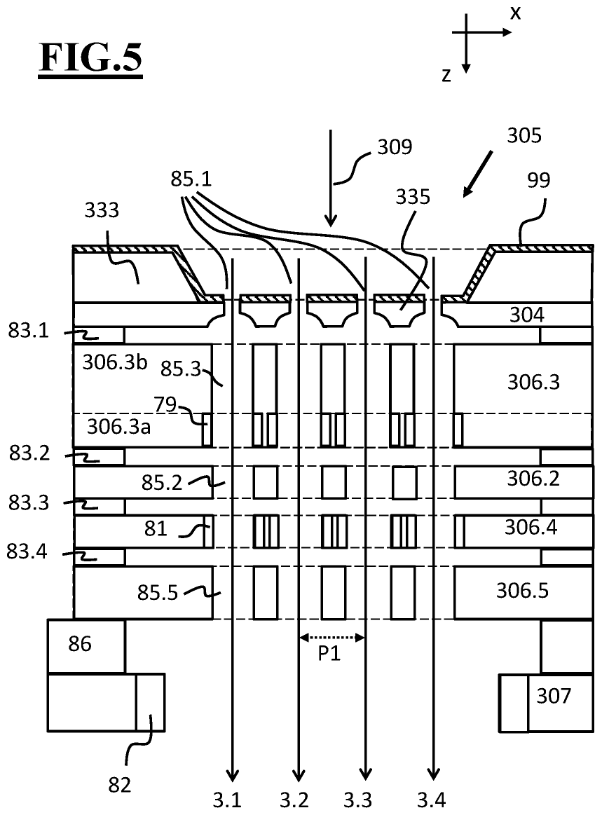

FIG. 5 illustrates a further example of the disclosure. The example of FIG. 5 is similar to the example of FIG. 3 and reference is made to FIG. 3. In FIG. 5, the order of the second multi-aperture plate or ground electrode plate 306.2 and the third multi-aperture plate or two-layer lens-let plate 306.3 is inverted, such that the plurality of primary charged particle beamlets is entering first the second layer or ground layer 306.3b of the two-layer lens-let plate 306.3 and intersects subsequent the second layer 306.3a comprising the plurality of ring electrodes. Downstream of the two-layer lens-let plate 306.3, the plurality of primary charged particle beamlets (3) including the beamlets 3.1 to 3.4 intersect the aperture of the ground electrode plate 306.2. By this arrangement, fewer scattered particles can impinge on the shielding layer 177 of the multi-layer stack MLS of the two-layer lens-let plate 306.3 and fewer disturbing charges can be generated in the MLS. The voltages provided during use to the plurality of ring apertures 79 can be controlled with higher precision and less fluctuations. In addition, the thickness of the MLS can be further reduced. For example, the thickness of the conductive shielding layer 177 at the bottom of the two-layer lens-let plate 306.3 can be reduced to about a=1 μm and the thickness of the MLS can be reduced to about 7 μm.

With the inverted arrangement of the two-layer lens-let plate 306.3, any flow of secondary or scattered electrons to the ring electrodes is significantly reduced with the ground electrode layer 306.3b upstream of the electrode layer 306.3a. Further, crosstalk is reduced with the deep aperture holes in the ground electrode layer 306.3b and x-ray or Bremsstrahlung is more effectively filtered before reaching the electrode layer 306.3a. The shielding layer 177 downstream of the electrode layer 306.3a can be reduced or even larger voltages can be provided. Therefore, a larger focusing range DF>1 mm, for example DF>3 mm can be achieved with the example of FIG. 5.

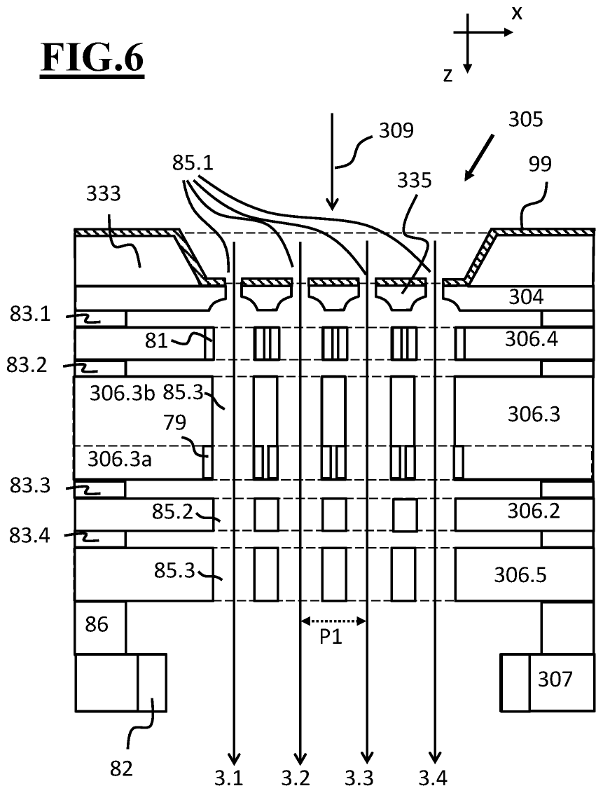

FIG. 6 illustrates a further modification of the disclosure. The example of FIG. 6 is similar to the example of FIG. 5 and reference is made to FIG. 3 and FIG. 5. In FIG. 6, the position of the multi-stigmator plate 306.4 is changed. The multi-stigmator plate 306.4 is arranged upstream of the two-layer lens-let plate 306.3. Thereby, a precise control of the intersection position of each beamlet 3.1 to 3.4 is possible and residual aberrations can be pre-compensated before entering the lens-lets of two-layer lens-let plate 306.3.

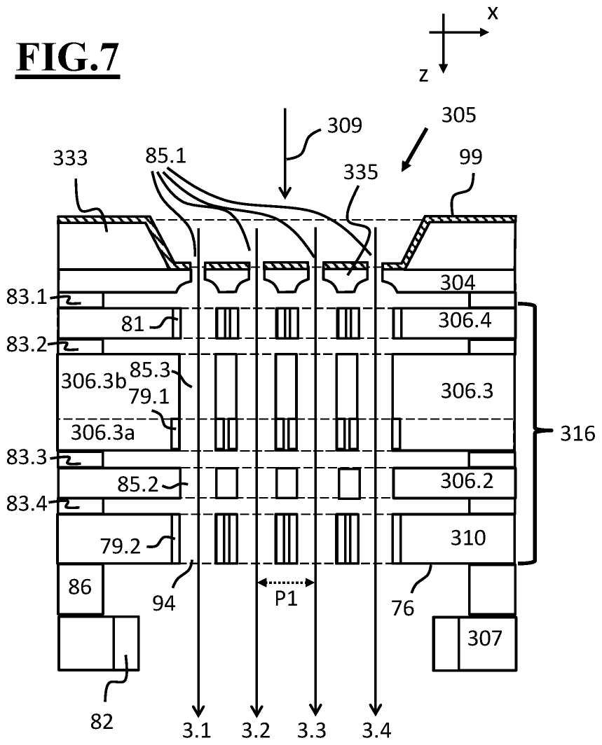

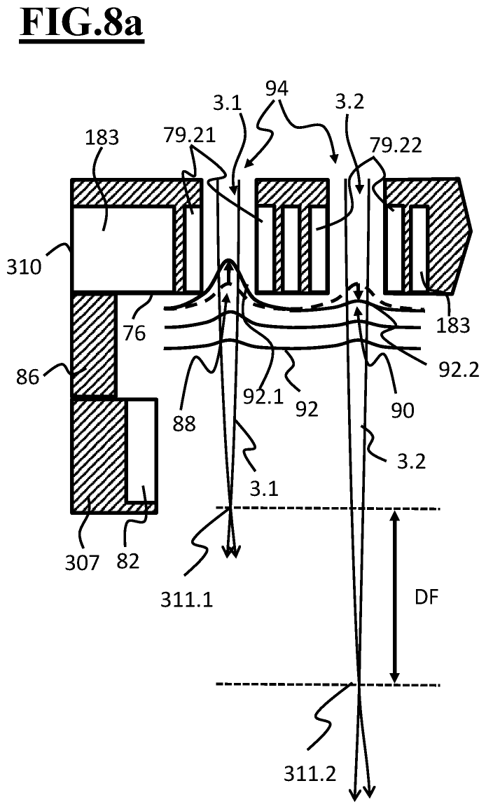

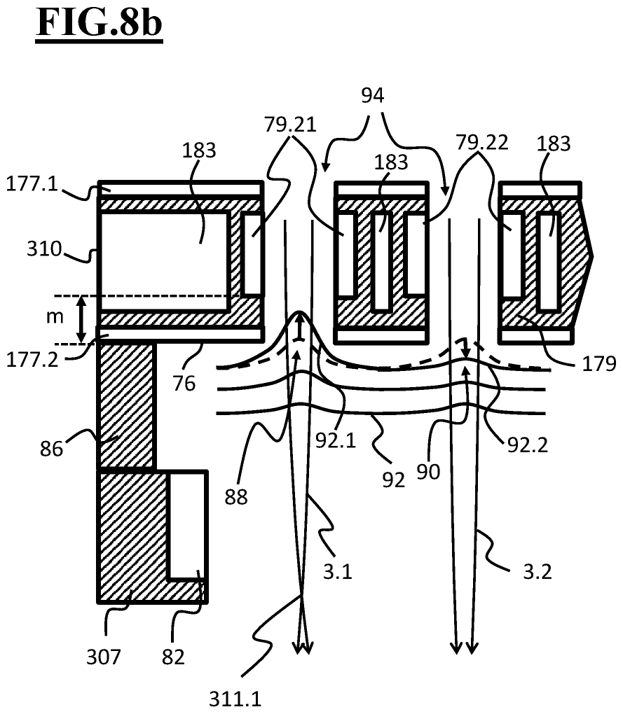

FIG. 7 illustrates a further example of the disclosure. FIG. 7 is similar to FIG. 6, but the hybrid lens plate 306.5 is replaced by a terminating multi-aperture plate 310, formed as a single lens-let layer. The terminating multi-aperture plate 310 comprises a plurality of ring electrodes 79.2 arranged around each or the plurality of terminating apertures 94 of the terminating multi-aperture plate 310. Each of the ring electrodes 79.2 is individually connected to a control unit 830, which is configured to provide during use a plurality of individual voltages to the ring electrodes 79.2 for an individual and independent manipulation of the penetration depth of the electrostatic lens-let fields 92 (see FIG. 8 below) into the terminating apertures 94. The function of the terminating multi-aperture plate 310 is illustrated in more detail in FIG. 8. With the ring electrode 82 of the electrostatic condenser lens 307, an electrostatic field 92 is generated between the terminating multi aperture plate 310 and the ring electrode 82. The electrostatic field 92 penetrates the terminating apertures 94 of the terminating multi-aperture plate 310 and forms micro-lens-lets (92.1, 92.2) in the terminating apertures 94, which contribute to the overall focusing power of the multi-beam generating unit 305. This is illustrated in FIG. 8a at the equipotential lines of the electrostatic lens-let field distribution 92. With the terminating multi-aperture plate 310, the penetration depth of the electrostatic lens-let field distribution 92 can be individually controlled by the plurality ring electrodes 79.2, forming individually adjustable micro-lens-lets. For example, a larger voltage difference relative to the voltage of the electrostatic condenser lens 307 is applied to a ring electrode 79.21, and during use a suction field 88 is generated. Therefore, a micro-lens-let 92.1 of larger power is generated and charged particle beamlet 3.1 is focused to focus point 311.1 at a shorter distance to the multi-beam generation unit 305. A smaller voltage difference relative to the voltage of the condenser lens 307 is applied to a ring electrode 79.22, and during use a suppression field 90 is generated. Therefore, a micro-lens-let 92.2 of smaller focusing power is generated and charged particle beamlet 3.2 is focused to a second focus position 311.2 spaced downstream of the first focus position 311.1. With the example of the electrodes 79.21 and 79.22 of FIG. 8a, a plurality of electrostatic micro-lens fields (92) such as the lens field 92.1 and 92.2 are individually formed or adjusted and a larger focusing range DF of the multi-beam generating unit can be achieved, for example DF>1 mm or DF>3 mm.

FIG. 8b shows some modifications of a terminating multi aperture plate 310. The terminating multi aperture plate 310 is covered by conductive shielding layers 177.1 and 177.2 on both sides. Both conductive shielding layers 177.1 and 177.2 are connected to ground and effectively shield the terminating multi aperture plate 310. Thus, the electrostatic micro-lens field (92) is prevented from penetrating into the terminating multi aperture plate 310, except for the terminating apertures 94. The plurality of electrodes 79.2 is further shielded by shielding aperture 183, which is connected to ground level. Thereby, cross talk is reduced. Thereby, an even larger focusing range DF of the multi-beam generating unit can be achieved, for example DF>3 mm.

The electrodes 79.2 can be formed at the lower edge of terminating apertures 94, such as illustrated in FIG. 8a. This has the advantage that a high sensitivity is achieved. The electrodes 79.2 can also be formed inside the terminating apertures 94 with a distance m to the bottom surface of the terminating multi-aperture plate 310, with the distance m selected between 2 μm<=m<=10 μm. A distance m can be for example given with m=4 μm or 6 μm. With a smaller distance m, a larger sensitivity can be achieved. With a larger sensitivity, lower voltages are used at the electrodes 79.2 to either suppress of enlarge the micro-lens-let 92.1 or 92.2. However, with a larger sensitivity, the terminating multi aperture plate 310 becomes also sensitive to aberrations or disturbances; therefore, for a more stable operation, a larger distance m>3 μm, for example m=4 μm or m=6 μm can be used. With a larger distance m, also the conductive shielding layer 177.2 and the isolating layer 179 between the electrodes 79.21 and 79.22 and the conductive shielding layer 177.2 can be provided with a larger thickness to prevent leakage of an electrostatic field into or out of the terminating multi-aperture plate 310. With the conductive shielding layer 177.2, also arcing between the field electrodes 79.2 and the condenser electrodes 82 is prevented and the field electrodes 79.2 and the electronical elements of the control unit (830) connected to the field electrodes 79.2 are protected from damage. The conductive shielding layers 177 can also be provided with plunging extensions 189 (not shown in FIG. 8) into the terminating apertures 94, as described above in more detail. With the leveling of the isolation layers 179 as described above (see FIG. 4 and corresponding description), a planar shielding layer 177.2 with high quality can be provided at the bottom surface 76, and the electrostatic lens-let field distribution 92 is be formed with high precision and low disturbances or aberrations.

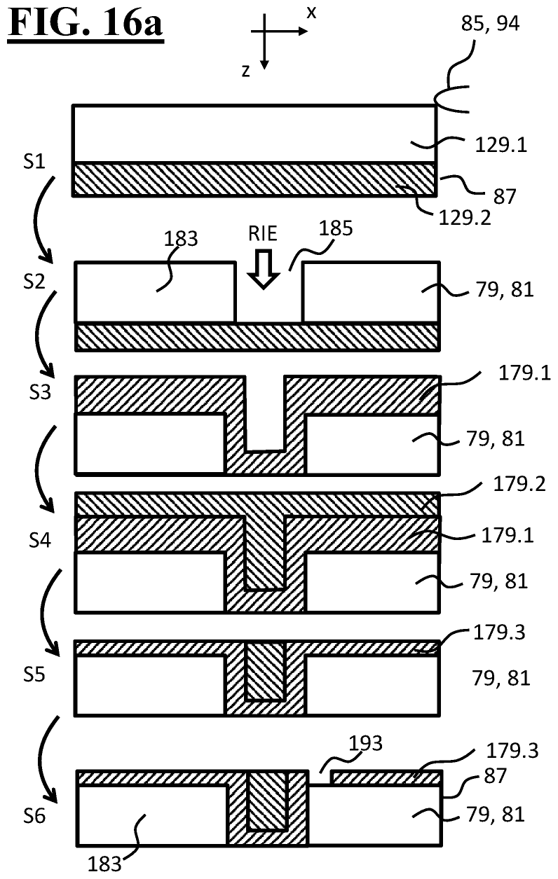

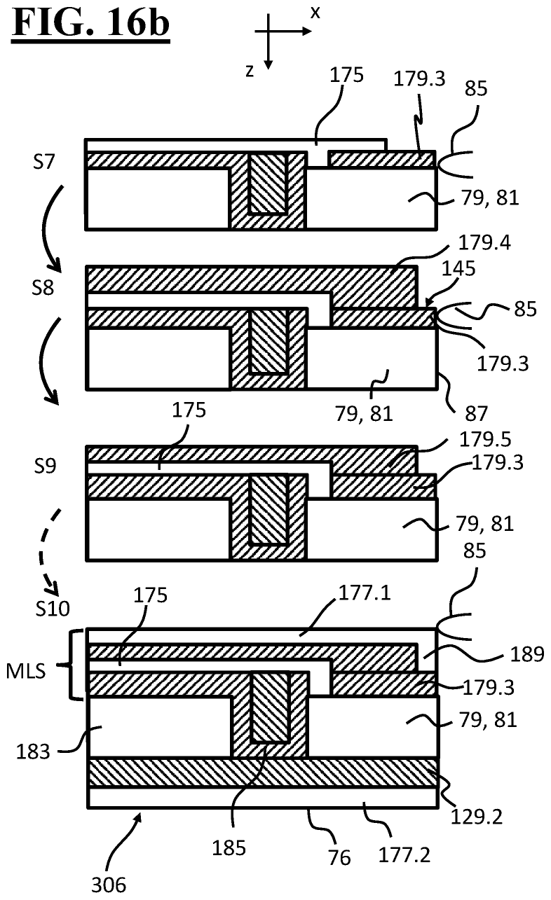

With the embodiment of FIGS. 7 and 8, an even larger focusing range DF as well as a larger variation of focus positions of the plurality of primary charged particle beamlets can be achieved and an even larger field curvature and tilt of the image plane 101 can be pre-compensated. The electrostatic lens-let field distribution 92 is changed with the individual voltages applied to the electrodes 79.2, and thereby an individual control of the focus positions 311 of the plurality of primary charged particle beamlets (3) is achieved with high efficiency. The variable electrostatic lens-let field distribution 92 of the actuated terminating multi-aperture plate 310 allows therefore a more effective pre-compensation of a field curvature. Since the plurality of lens effects of the variable electrostatic lens-let field distribution 92 is a first order effect, lower voltages are used to achieve a larger effect on the change of the focusing power of each variable electrostatic lens-let field distribution 92, for example lens-let field distribution 92.1 or 92.2. The change of each variable electrostatic lens-let field distribution 92.1 or 92.2 can also be in either positive of negative direction. Therefore, already with moderate voltages of about more than +/−20V, a large focusing power can be achieved. The focusing power is especially larger as with the Einzel-lenses described above with a voltage of for example more than 50V or 100V. With similar voltage differences of about +/−25V or +/−50V at the terminating apertures 94, a focusing range can be adjusted over a z-range at least twice as large compared to Einzel-lenses. With the improved methods of fabrication and a mechanism for shielding of electrostatic fields as described for example at FIG. 4 and FIG. 16 below, terminating aperture plates 310 can be fabricated with high precision, such that even larger voltage differences exceeding +/−50V can be applied, for example +/−100V or more, and an even larger focusing range can be achieved.

The terminating apertures 94 of a terminating multi aperture plate (310) have diameter of DT. At the example of FIG. 7, some examples of the diameters of the apertures 85.1 to 85.4 are described. The terminating aperture has the largest aperture, which is typically in a range of 1.6×D1<=DT<=2.4×D1. Thereby, the primary beamlets formed at filter aperture 85.1 have a smaller diameter than the termination aperture. On the other hand, the diameter of the termination aperture is constrained such that larger focusing power by the electrostatic micro-lens field (92.1, 92.2) can be achieved. The diameter of the second apertures, here the apertures 85.4 of the multi-stigmator plate 306.4, is given by D2. D2 is between D1 and DT with 1.4×D1<=D2<=0.75×DT. The third apertures 85.3 of the two-layer lens-let plate 306.3 have a diameter D3 between D2 and DT, with 1.4×D1<=D2<=0.9×D3<=0.8×DT.

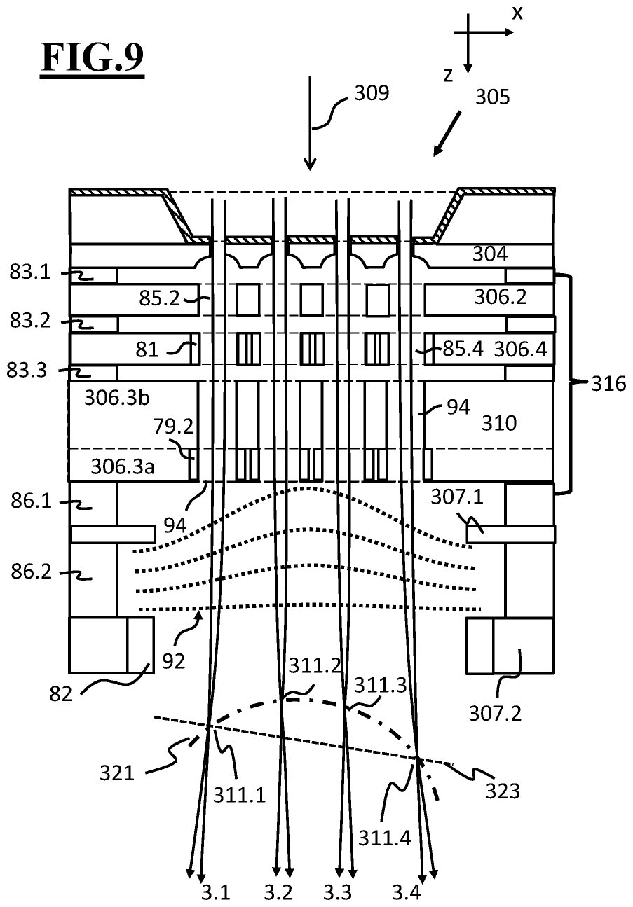

FIG. 9 shows a further modification of FIG. 7, and reference is also made to the description of FIGS. 7 and 8. Opposite to FIG. 7, the single lens-let layer of the terminating multi-aperture plate 310 is changed to a two-layer lens-let plate, forming the terminating multi-aperture plate 310. Further, the position of the ground electrode plate 306.2 is changed to the position between the filter plate 304 and the multi-stigmator plate 306.4. As described above with reference to FIG. 3, with a constant voltage offset to each of the eight electrodes of the multi-stigmator plate 306.4 at each of the plurality of apertures 85.4, the multi-stigmator plate 306.4 is configured to form during use together with ground electrode plate 306.2 and the ground layer 306.3b a plurality of adjustable Einzel-lenses. With the round electrodes 79 of the ring electrode layer 306.3a of the inverted two-layer lens plate forming the terminating multi-aperture plate 310, the penetration depth of the electrostatic field into the apertures 94 of the terminating multi-aperture plate 310 can be controlled during use, as described in FIG. 8. In this example, the electrostatic condenser or field lens 307 comprises a first ring electrode 307.1 and a second ring electrode 307.2. The first ring electrode 307.1 can for example be connected to ground level, the second electrode 82 to a high voltage of for example 25 kV or more. The electrostatic field 92 generated by the electrostatic condenser with field lenses 307.1 and 307.2 is illustrated by equipotential lines. With the arrangement of a multi-stigmator plate 306.4 upstream of the terminating multi-aperture plate 310, each of the primary charged particle beamlets (3), comprising the beamlets (3.1-3.4), can be deflected or shaped before it enters the corresponding terminating aperture 94. Thereby, for example an aberration of the variable electrostatic lens-let field distribution 92 can be pre-compensated.

With the combined action of the plurality of Einzel-lenses controlled by the offset voltages at the plurality of apertures of the multi-stigmator plate 306.4 and the control of the penetration depth of the electrostatic micro-lens field 92 into the terminating apertures 94 of the ring electrode layer 306.3a with the plurality of ring electrodes 79, the position of the focus points 311.1 to 311.4 of the beamlets 3.1 to 3.4 can be precisely controlled to match the predetermined intermediate image surface 321 with a tilt component 323. With the multi-stigmator plate 306.4, the lateral positions of the plurality of focus spots 311 can further be controlled and adjusted, as well as astigmatic aberrations can be pre-compensated during use. Thereby, a curvature of an intermediate image surface 321 can be achieved in order to pre-compensate a field curvature and image plane 323 tilt of the charged particle imaging system downstream of the multi-beam generating unit 305 (see FIG. 1). The curvature of the intermediate image surface 321 is—in propagation direction of the primary charged particle beamlets—of convex shape, such that the center of curvature of the curved intermediate image surface 321 is downstream of intermediate image surface 321.

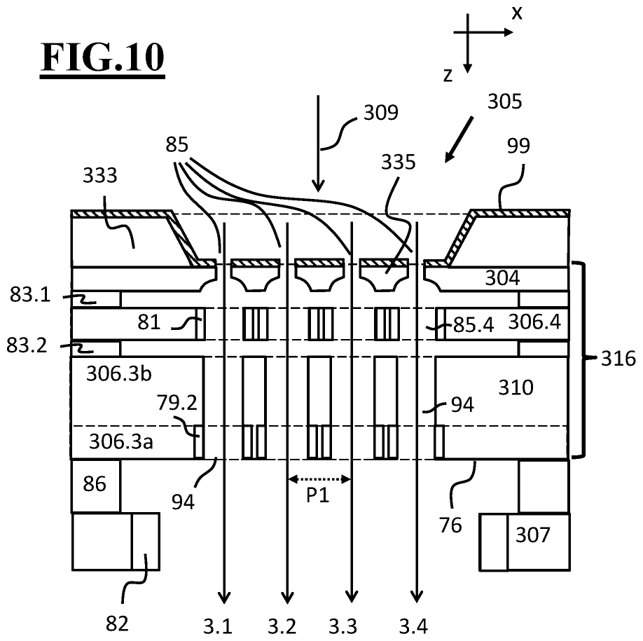

FIG. 10 illustrates a further modification to FIG. 9 and reference is made to FIG. 9. Here, the ground electrode plate 306.2 is omitted. The filter plate 304 can be provided with an electrode layer 98 as illustrated in FIG. 2 (not shown in FIG. 10).

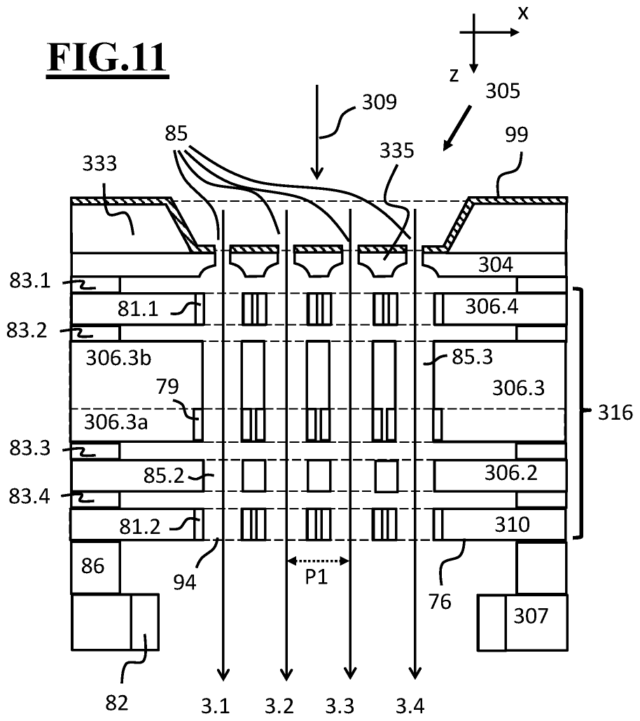

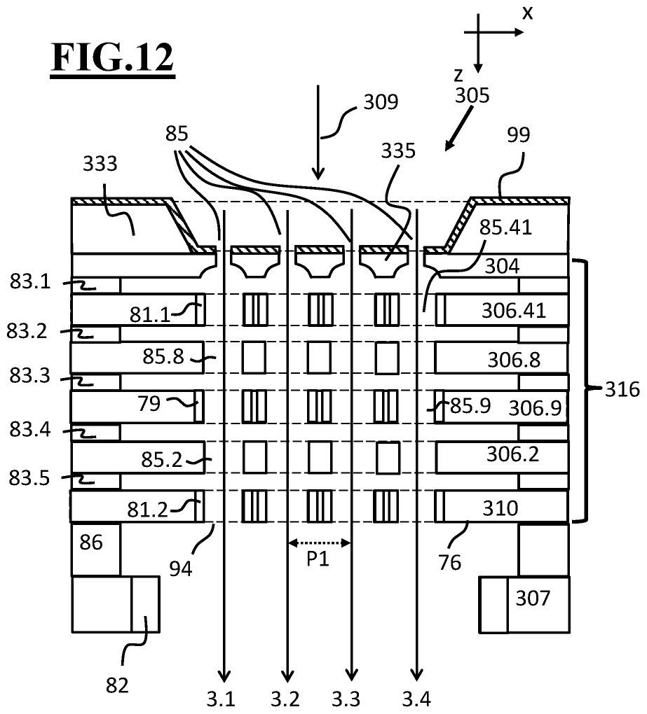

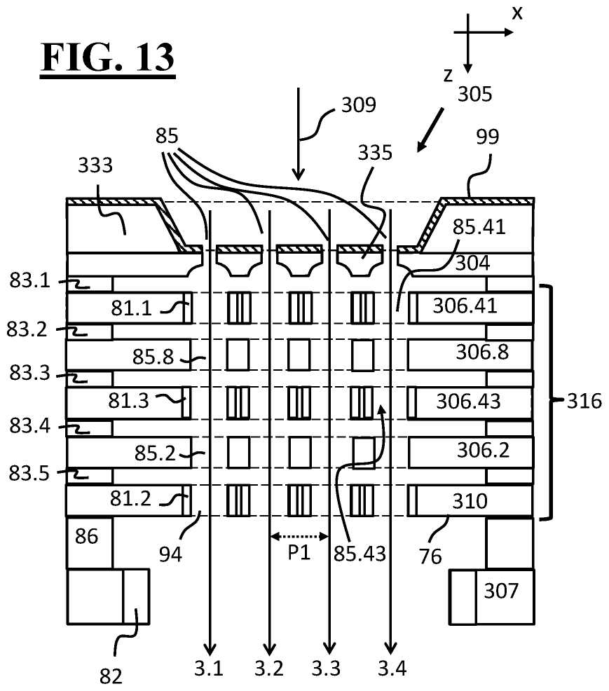

The precision of the aperture edges of the last multi aperture plate 306.3 at the bottom side can be considered for the precision of the penetration field and thus for the electrostatic micro-lens field 92. The aperture edges is therefore produced with high accuracy. FIG. 11 shows a modification of FIG. 7 and reference is made to FIGS. 7 and 8. The example of FIG. 11 comprises two multi-pole elements 306.4 and 310 and one ring electrode 79 for each of the plurality of primary charged particle beamlets 3.1. to 3.4. The difference to the example of FIG. 7 is the arrangement of a second multi-stigmator plate forming the terminating multi-aperture plate 310 in replacement of the single lens-let layer of FIG. 7. With the terminating multi-stigmator plate 310, a control of the penetration depth of the electrostatic condenser field can be achieved by application of a constant voltage offset to the eight electrodes at each terminating aperture 94 in a similar manner as described in FIG. 8. In addition, the penetration field can be shifted and shaped and a tilt and an astigmatic correction of each beamlet can be achieved individually. With this example, deviations from the ideal shape of the aperture edges of the last multi aperture plate 310 at the bottom side 76 can compensated electro-optically by providing of predetermined compensation voltages to each of the multi-pole electrodes 81.2. These voltages can for example be determined in a calibration step. FIG. 12 illustrates a further variation of the example of FIG. 11, with the two-layer lens-let plate 306.3 replaced by a ground electrode plate 306.8 and a lens electrode plate 306.9, spaced by an additional spacer. FIG. 13 illustrates a further variation of FIG. 12 with the lens electrode plate 306.9 replaced by a further multi-stigmator plate 306.43. Here, individual lens action for each of the beamlets 3.1 to 3.4 can be achieved by different methods. A first and second focusing power is achieved during use by application of an offset voltage to a set of eight apertures of any of the multi-stigmator plates 306.41 and 306.43 for forming Einzel-lenses with the ground electrodes 306.2 and 306.8. A third focusing power is achieved during use by application of an offset voltage to a set of eight apertures of the terminating multi-aperture plate 310 to achieve a suction field 88 or a suppression field 90 as illustrated in FIG. 8. A fourth method of generating during use a focusing power is achieved by generating a sequence of quadrupole fields as described in DE 102020107738 B3, which is incorporated hereby by reference. Each quadrupole field of each of the at least three multi-pole elements is rotated with respect to each other, and thereby a stigmatic focusing can be achieved. It is understood that the individual voltages supplied to the multi-stigmator arrays 306.41, 306.43 and the terminating multi-aperture plate 310 to change or adjust a focusing power can each be adjusted to achieve during use an additional correction of the lateral beam spot position and an additional correction of astigmatism. It is further understood that in the examples having more than one multi-stigmator plates 306.4 or 310, the multi-pole elements can be at different rotation angle for each of the multi-stigmator plates 306.4 or 310, and higher order astigmatism or trefoil aberrations can be compensated as well. By combined control of each of the consecutive electrodes 79 and 81 in the plurality of multi-aperture plates 306.3 to 306.9 and 310, including the terminating multi-aperture plate 310, of the examples of FIG. 7 to FIG. 14, a plurality of multi-stage micro-lenses 316 are formed, with increased focusing power or focusing range DF of more than DF>1 mm, such as DF>3 mm, including DF>5 mm, for example DF>=6 mm.

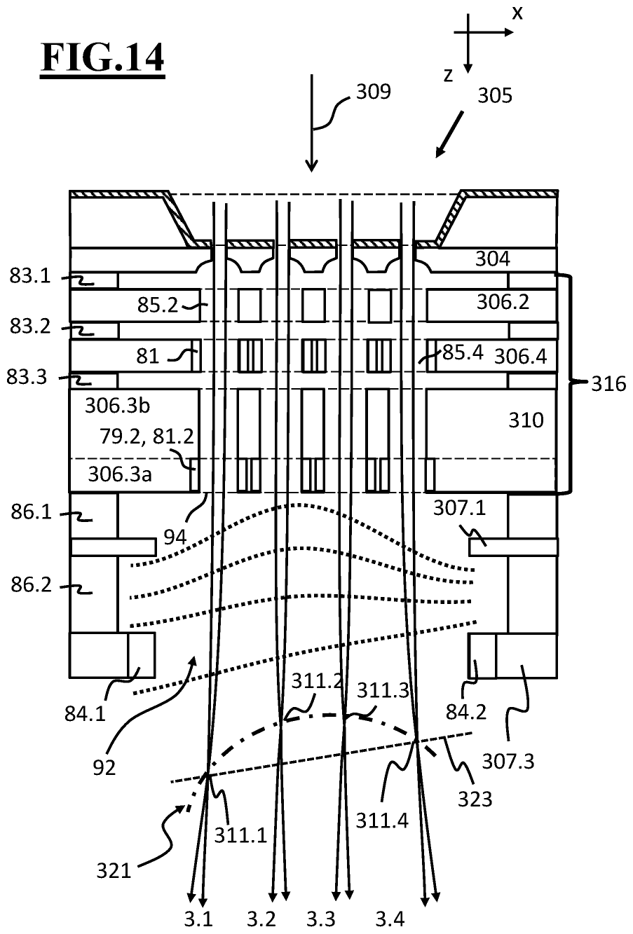

FIG. 14 illustrates another variation of the example described in FIG. 9. Opposite to the example of FIG. 9, the round electrode 82 of the electrostatic condenser lens 307 is split into ring segments, for example four or eight ring segments 84.1 to 84.8, thus forming a quadrupole or octupole element. Therefore, the electrostatic micro-lens fields 92 penetrating during use into the terminating apertures 94 of the terminating multi-aperture plate 310 have for example an asymmetry or inhomogeneity generated by the ring segments 84.1 to 84.8 of the segmented aperture 84. With these segments of the ring electrode 84, for example a linear variation of the electrostatic micro-lens field 92 can be introduced as illustrated by the equipotential planes. Thereby, a desired tilt of the intermediate image 321 can be facilitated. A residual tilt of the plurality of primary charged particle beamlets (3) can be compensated by an additional deflector downstream of the electrostatic condenser lens 307 (not shown in FIG. 14).

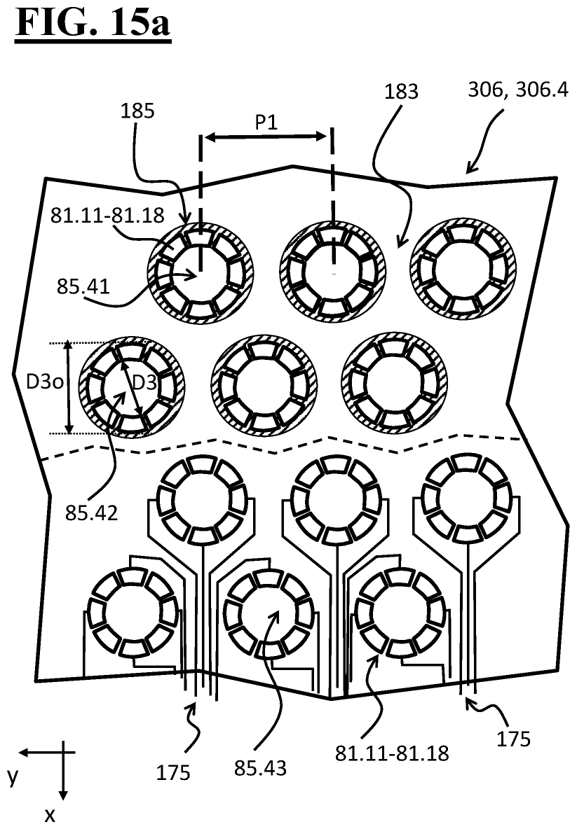

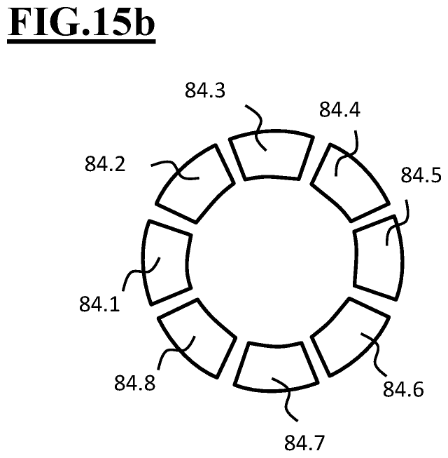

FIG. 15a illustrates schematically a top view of a multi-stigmator plate 306.4 with eight electrodes 81.11 to 81.18 for each aperture 85.4 (only three marked by 85.41, 85.42 and 85.43). The eight electrodes 81.11 to 81.18 form together the multi-pole electrode 81, capable of for example deflecting or shaping a transmitting primary beamlet. Each of the plurality of multi-pole electrodes 81 is connected to a voltage supply by wiring connections 175. During use, a plurality of low voltages in the range of −20V to 20V is applied to the plurality of electrodes. Each ring of electrodes 81.11 to 81.18 is isolated by isolation gap 185 from the electrically conductive bulk material, which forms a shielding layer 183 between the multi-pole electrodes 81. The shielding layer 183 is connected to ground level. The multi-pole electrode 81 are therefore embedded in the bulk material, both formed of for example doped silicon. The multi-stigmator plate 306.4 is further covered with a shielding layer (not shown in FIG. 15a).

Each electrode ring 79 or 81 in the circumference of a corresponding aperture 85 or 94 has a width of between 6 μm to 15 μm, for example 12 μm. The diameter D3 of an aperture 85 or 95 is for example given with 50 μm<=D3<=70 μm. The diameter D3o of each electrode ring is therefore between 65 μm<=D3<=95 μm. The minimal pitch P1 is typically limited by the diameter D3o and the remaining isolating gap formed by the shielding layer 183 between two adjacent electrode rings 79 or 81. With minimum shielding distance of about 10 μm, such as about 15 μm, the pitch P1 can be selected with P1>=75 μm, for example P1=100 μm or P1=150 μm. Generally, a smaller width of the electrodes reduces the volume and therefore the capacity of each electrode. A smaller capacity is of advantage for a faster change of the electrostatic field generated by the electrode. A larger capacity provides more stability with respect to fluctuating charges or a charge diffusion. The dimension of the capacity of the electrodes is therefore selected according to the desired temporal properties for changing an electrostatic field or keeping constant an electrostatic field. Typically, cylinder electrodes 79 are provided with a ring width of about 15 μm, thereby providing a large capacity with a high stability of the electromagnetic lens field. Typically, multi-pole electrodes 81 are provided with a smaller width of for example 6 μm, thereby each electrode 81.1 to 81.8 is configured with a small capacity with a high speed for changing the electromagnetic multi-pole field.

FIG. 15b illustrates schematically the segments of the ring electrode 84, comprising segments 84.1 to 84.8, for application of an electrostatic field with a linear gradient.

FIGS. 16a and 16b illustrate an example for fabricating a multi-aperture plate 306, such as the lens electrode plate 306.9, a lens electrode layer 306.3a of two-layer lens-let plate 306.3, a multi-stigmator plate 306.4, or a terminating multi-aperture plate 310. A cylindrical aperture 85, 94 is indicated by a semi-circle and is throughout the steps S1 to S11 on the right side of the illustration. The apertures can be formed either in advance of step S1 and protected during steps S2 to step 11 with a removable protective coating such as photoresist. In an alternative solution, the apertures can be formed after formation of the steps S1 to S11 by lithographic processing and well-known etching techniques.

The coordinate system is chosen in accordance with the coordinate system in figure one, with the positive direction of the z-axis in propagation direction of the primary charged particle beamlets. The positive z-direction and the propagation direction is in normal sense “downwards”. Irrespective of the positive z-direction pointing “downwards” in FIG. 1, FIG. 2 or FIG. 16, the “upper” plane or position refers to a plane which is first intersected by a primary charged particle beamlet and a “lower” or “bottom” plane or position refers to a plane which is intersected by a primary charged particle beamlet afterwards. In the selected coordinate system, an “upper” position therefore has a lower z-coordinate as a lower or bottom position.

In step S1 an SOI wafer is provided with two layers, a first, top layer 129.1 and a second layer 129.2. The thickness of the layers is typically between 30 μm and 300 μm. The second layer 129.2 is formed as a Silicon oxide layer (for example silicon dioxide). The second layer 129.2 can have a reduced thickness by leveling down the thickness of the second layer 129.2 by chemical mechanical polishing (CMP) to about below 2 μm or less, for example 1 μm or even 0.2 μm. The top layer 129.1 has for example a thickness of 50 μm.

In an alternative example, the SOI wafer comprises a third layer (129.3, not shown) of for example 200 μm thickness for providing a ground electrode layer of the two-layer lens-let plate 306.3. The first layer and the optional third layer (129.1, 129.3) consist of doped silicon and have a finite conductivity, such that electrodes can be directly formed in the first or third layer.

In a step S2, circular rings are formed into the device layer 129.1, forming the isolation gap 185 between the electrodes 79 and the bulk material 183. For multipole electrodes 81, further trenches or isolation gaps for separation of the multipole electrodes are generated by RIE etching.

In step S3, a thick electrical isolation layer 179.1 is formed for example the thermal oxidation, thus forming a Silicon oxide film (silicon dioxide) of approximately 2-3 μm thickness (Note: in step 3 and further steps, the illustration of the second layer 129.2 has been omitted).

In step S4, the remaining gap in electrical isolation layer 179.1 in the isolation gap is filled and a partial planarization by deposition of a Silicon-oxide film 179.2 (oxide from the decomposition of the TEOS gas; TEOS=Tetraethyl orthosilicate) is achieved.

In step S5, unnecessary parts of the SiO₂-layer 179.2 and partially the Silicon Oxide layer 179.1 are removed by CMP (chemical mechanical polishing), thus a constant and planar isolation layer 179.3 of about 2 μm thickness or less is formed, for example with a thickness of 1 μm or even 0.5 μm. Thereby, a thick Silicon dioxide layer is avoided, and stress is reduced. Furthermore, with the planarized Silicon oxide layers, the further photolithographic processing of the multi-aperture plate can be performed with higher accuracy. The SiO₂-layer of reduced thickness is also advantageous for further etching steps. During the etching of the apertures and other fine structures, the contours are defined by a photoresist masking layer. The planarization for example by CMP and the reduced thickness improves the accuracy of edges and sidewalls of the etched structures, which is used for low-aberration performance of the electrostatic elements.

The both issues of thick and uneven silicon dioxide layers contribute for unreliable and unreproducible etch sequence and formation of defects (under-etchings, hole defects, rough walls). Such defects and rough sidewalls are known origins of astigmatism and high order aberrations. It is one aspect of the disclosure that with the leveling of the planarized Silicon dioxide layers or isolation layers according to step S5, these issues are avoided.

In Step S6, an opening for a wiring contact 193 is formed in the isolation layer 179.3 at the remote position from the inner aperture sidewall 87.

In step S7, a conductive layer is formed above the planarized isolation layer 179.3. The conductive layer can for example be an Aluminium or Copper layer of 1 μm thickness. The conductive layer can also be formed by gold with a thickness of between 50 nm-200 nm. The conductive layer 175 is photolithographically structured in a way such that to every electrode 79 or 81 a predetermined individual voltage can be individually provided by the electrical wiring connections 175 (only one shown).

In step S8, a further isolating TEOS layer 179.4 is formed to completely cover the plurality of wiring connections 175. The TEOS layer 179.4 is photolithographically structured to form a gap 145 with the inner wall 87 of the aperture.

In step S9, the isolating TEOS layer 179.4 is polished down by CMP, and a residual isolating TEOS layer 179.5 is formed with a thickness of about 0.5 μm to 2 μm above the wiring connections 175. The step S9 can also be performed before the photolithographic structuring in step S8.

In step S10, the conductive shielding layer 177.1 is formed by metal deposition on the residual isolating Silicon Oxide layer 179.5 and forming the plunging extension 189 in the gap 145. The metal film is formed with a thickness of up to 2 μm, for example 1 μm, to provide enough shielding of electrical fields and to absorb scattered charged particles.

In two further optional steps between step S9 and S10, a stress compensation layer formed of SiNx is deposited on the residual isolating TEOS layer 179.5 and a further Silicon dioxide isolating layer is provided to cover the stress isolating layer. The isolating layer can again be planarized with chemical mechanical polishing. With PECVD (plasma enhanced chemical vapor deposition), a desired stress varying from ca. −1 GPa (compressive) to +1 GPa (tensile) of SiNx can be achieved depending on the composition x and on the deposition parameters.

In a further optional step S11 (not separately shown), the bottom side 76 can further be covered by a conductive shielding layer 177.2 similar as layer 177.1 on the beam upper side. Obviously in case of a third layer 129.3, the second conductive shielding layer 177.2 is formed on the bottom side of the third layer 129.3. The conductive layer 177.2 can be formed by an Aluminium layer of 2 μm thickness. Both shielding layers 177.1 and 177.2 are connected to ground and prevent a leakage of electrical fields into the multi-aperture plates 306. The second shielding layer 177.2 can be considered for inverted arrangement of multi-aperture plates 306.3, such as illustrated in the examples of FIGS. 5, 6, 9 to 11 and 14. However, an inverted arrangement is not limited to the inverted arrangement of two-layer lens-let plate 306.3, and also other multi-aperture plates such as multi-stigmator plates 306.4 can be arranged inverted, i.e. with the wiring connections 175 in the propagation direction of the charged particles behind or after the electrode layer. In such a configuration, the wiring connections 175 are well covered and less sensitive to scattered charged particles, and for example induced charges are reduced or completely prevented from the electrodes 79 or 81. In the inverted arrangement, the wiring connections 175 are also better protected from bremsstrahlung, created at the top surface of the filter plate 304. In some examples of the inverted arrangement, the shielding layer below or downstream of the wiring connections 175 can therefore even be omitted.

In an optional step S12 (not shown), the shielding layers 177.1 and 177.2 can further be planarized by additional polishing, for example with CMP-processes.

With the process steps provided in FIG. 16, larger voltages can be provided for a larger focussing stroke. In addition, with the thinning of the Silicon oxide layers by CMP, less stress induced deformation is introduced, and multi-aperture plates 306 fabricated according to process steps S1 to S12 are less sensitive to thermal changes.

With the process steps S1 to S12, a multi-aperture array 306 with a plurality of electrodes with individual metal wiring connections 175 within thin isolation layers and a conductive shielding layer 177.1 is produced with significantly reduced thickness of the MLS below 6 μm, such as below 5 μm. Several isolator layers 179.1 to 179.5 are used at the surface of the first electrode layer 129.1 to fill the isolation gap 185, to form isolation layers of the metal wiring connections 175 and to isolate the conductive shielding layer 177.1. With the chemical mechanical polishing (CMP), the isolation layers are subsequently polished and planarized and thus the forming of layers or structures such as the wiring connections can be performed with higher accuracy. In addition, subsequent etching processes for etching of the apertures or forming of wiring connections or other structures are significantly reduced.

With the CMP, multi-aperture arrays 306 can be produced with higher repeatability. With the planarization, the conductive shielding layer 177.1 is formed with higher quality and electrical fields can be controlled with high precision.

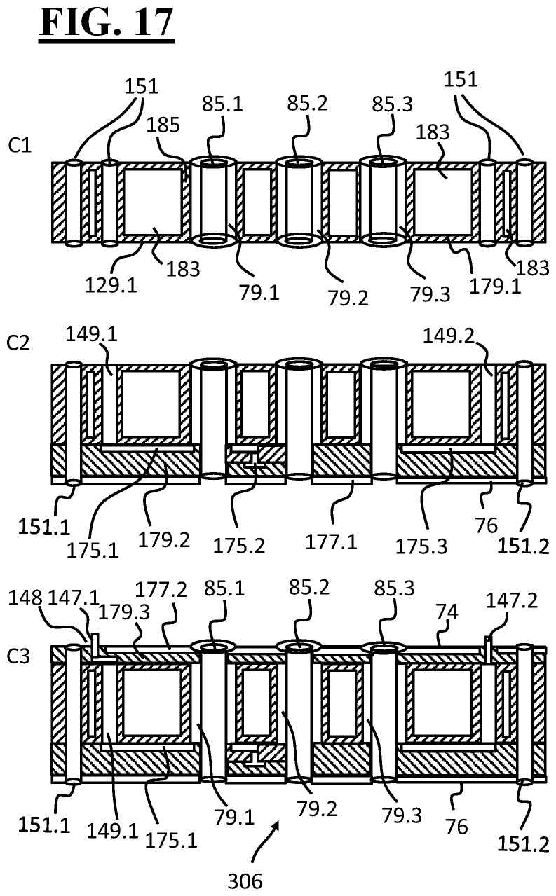

With the inverted arrangement of two-layer lens-let plate 306.3 or of other multi-aperture plates 306, the electrical wiring connections 175 can be on both sides of multi-aperture plates 306. FIG. 17 illustrates a method of fabrication and wiring the electrical wiring connections 175 through a layer of a multi-aperture plate 306. With through-chip wiring connections, it is possible to electrically contact each multi-aperture plate 306 form the upper side such that an inverted arrangement is not limited.

In step C1, an electrode layer 129.1 is provided similar as in step S6 described above. The electrode layer 129.1 with a thickness of 50 μm to 150 μm is made of bulk material 183, for example doped silicon. The electrode layer can also by formed with a larger or smaller thickness between 30 μm to 300 μm. With thermal oxidation, a first isolation layer 179.1 is formed in the isolation gaps and on the outer surfaces of the electrode layer 129.1.

In step C2, a plurality of wiring connections for the voltage supply, including the wiring connections 175.1, 175.2 and 175.3 are lithographically formed at the lower side of the electrode layer 129.1. A set of through holes 151 is filled with conducting material such as metal or doped Silicon, forming through connections 149.1 and 149.2. The number N of through connections 149 is corresponding to the number N of individually addressable ring electrodes 79 (or, in analogy, multipole electrodes 81). Each individually addressable ring electrodes 79 is connected to one through connections 149, for example, ring electrode 79.1 is connected to through connection 149.1. All connections are fabricated at the bottom or lower side of the electrode layer 129.1. Further isolating layers 179.2 are provided to isolate the wiring connections 175. Chemical mechanical polishing can be applied after each deposition step to generate a planar surface for next photolithographic and etch processing steps. Finally, a conductive shielding layer 177.1 is applied to the bottom or lower side 76 of the electrode layer 129.1.

In step C3, the through connections 149.1 and 149.2 on the upper side 74 are connected to connection or soldering pins 147.1 and 147.2. These pins or pads 147 are situated at the periphery of the multi-aperture plate, far away from the apertures and charged particle beamlets. A further isolation layer 179.3 is provided. Finally, a conductive shielding layer 177.2 is provided, isolated from the soldering pins 147 including the soldering pins 147.1 and 147.2. Plunging extensions can be fabricated for each of the conductive shielding layers 177.1, 177.2, as described above (not shown in FIG. 17).

A plurality of aperture holes, including the apertures 85.1 to 85.3. is etched through the electrode layer 129.1, for example after steps C2 and C3. Each aperture 85.1 to 85.3 has a diameter of about 50 μm to 70 μm and a plurality of isolation gaps 185 for the ring electrodes 79.1 to 79.3 is formed. In an example, the apertures can be defined lithographically and etched through by vertical deep RIE (DRIE), after the isolation gaps 185 have been formed on the electrode layer.

In addition, in the peripheral circumference of the electrode layer 129.1, through holes 151 are generated by etching. The through holes 151 can be significantly smaller, for example below 10 μm, or even below 2 μm. Some through holes 151.1 and 151.2 are generated for alignment or the electrode layer 129.1 with other multi-aperture plates 306 or spacers 83. With the through connections 149, each of the plurality of ring electrodes 79 of a single lens-let plate or lens electrode plate 306.9 or a two-layer lens-let plate 306.3 can be electrically connected from the opposite site, opposite to the side of the wiring connections 175. In analogy, each of the plurality of multi-pole electrodes 81 of multi-stigmator plates 306.4 can be electrically connected from the opposite site, opposite to the side of the wiring connections 175. With the through connections 149 and the process steps C1 to C3, it is also possible to connect ring electrodes 79 or multipole electrodes 81 from both sides, while the connections to control devices such as to the primary beam path control module 830 is achieved only from one side of a multi-aperture plate 306.

It is understood that several variations of the process are possible. For example, the through holes can be generated initially and can be filled with for example conductive material even before step C1, and the alignment holes 151.1 and 151.2 are opened by etching in step C2.

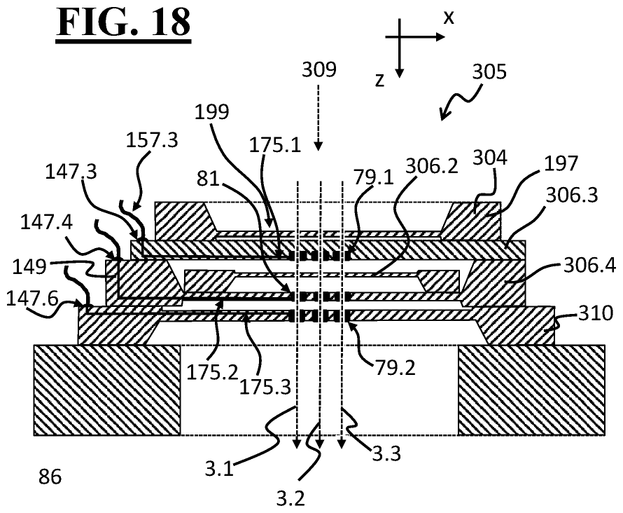

FIG. 18 illustrates the alignment and stacking of a plurality of multi-aperture plates, including an inverted lens electrode plate 306.9. Advanced multi-beam charged particle systems for wafer inspection involve complex multi-beam generating units 305 or multi-beam deflecting units 390 (see FIG. 1). According to the examples of the disclosure, a multi-beam generating unit 305 is formed by stacking at least three multi-aperture plates 306 with spacers. A first multi-aperture plate or filter plate 304 is used for dividing an incident beamlet 309 and generating a plurality of primary charged particle beamlets 3, including beamlets 3.1 to 3.3. In the example of FIG. 18, three multi-aperture plates 306.3, 306.4 and 306.9 are used for individually focusing of each of the plurality of transmitting charge particle beams 3.1 to 3.3 with large focusing power or large stroke. At least one multi-stigmator array 306.4 is utilized to control the lateral position of each of the beamlet 3.1. to 3.3 and to pre-compensate any residual astigmatism. With the through-contacts 149 it is possible to provide wiring connections 175, such as for example the wiring connection 175.1 and 175.2 at the bottom side of corresponding inverted multi aperture plates 306.3 and 306.4. Thereby, any unwanted charging of the wiring connections by scattered charged particles is minimized and residual stray fields of the wiring connections 175 are minimized. With the through-contacts 149 it is possible to provide solder pins 147, including solder pins 147.3, 147.4 and 147.6, at the top or upper surface of each multi-aperture plate 306.3, 306.4 and 306.9, respectively. Via the solder pins 147.3, 147.4 and 147.6, wiring connections 157 (only 157.3 identified in FIG. 18) are established to a control unit 830 (not shown in FIG. 18) and individual voltages can be provided to the plurality of ring electrodes 79.1 and 79.2 as well as to the plurality of multipole electrodes 82. The multi-aperture plates 306 can be stacked in optimized predetermined orientation. With at least three through holes 151 (not shown in FIG. 18; see FIG. 17), a precision alignment of the stack of multi-aperture plates is achieved.

In addition to the through-connections 149, two multi-aperture plates 306 can be attached to each other with flip chip bonding techniques (eutectic or thermo-compression bonding) and an electrical contact to a first multi-aperture plate can be established through a through-connection 149 of the second multi-aperture.

The stack of multi-aperture plates 306 can comprise spacers for stacking the multi-aperture plates at predetermined distances. In the example of FIG. 18, supporting zones 197 of predetermined thickness are provided in the periphery of the membrane zones 199 or the multi-aperture plates 306. With such a membrane-in-frame configuration it is possible to adjust the membrane zones 199 of adjacent multi aperture plates at a small gap of about several μm and laterally align and adjust the aperture openings with high accuracy of below 1 μm, such as below 0.5 um. Furthermore, the stack of multi-aperture plates can be fixed with the supporting zones or frames 197 by application of a significant force or pressure.

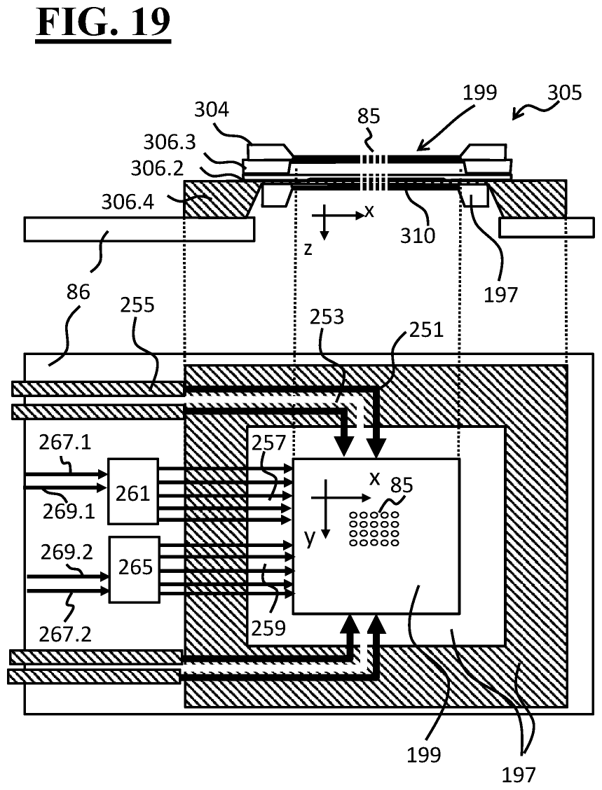

To enhance the performance of the multi-beam charged particle microscope during use, each of the plurality of charged particle beamlets is individually controlled, for example by individual focus correction with a plurality of individually controlled ring electrodes 79, or a plurality of individually controlled electrodes 81 of stigmators or deflectors. The individual control of the plurality of electrodes is provided by wirings, additional wirings are provided for shielding and absorbing layers described above, or for sensors. One multi-beam raster unit for a plurality of for example N=100 beamlets comprises about 1000 or more electrodes, with about 1000 or more than 1000 individual wiring connections. The electrodes and shielding or absorbing layers involve drive voltages with differences of orders of magnitude, for example between 10V up to 1 kV. For example, multi focus correction involves 100 high voltage wirings for about 200V and multi astigmatism correction involve for example 800 low voltage wirings for few volts with very low noise, and an absorbing layer produces a high current. Wirings with such voltage differences can easily influence each other and thereby diminish the performance of a multi-beam generating unit 305. In an embodiment, a multi-beam generating or raster unit 305 comprises design features and structures to minimize influences of the voltage differences. A multi-beam raster unit comprises a mixed signal architecture for different voltages and currents. High voltages are provided by an external controller. Low voltages provided by ASICs placed inside the vacuum with digital interface to an external controller. The routing of signals and voltage supply is obtained via a UHV-Flange. A separation of the wirings with different voltages is achieved by supply of the voltages from different directions. With the first direction (the z-direction) of the transmitting charged particle beamlets, for example the low voltages are supplied from a second direction (the x-direction), and the high voltage is supplied from a third direction. The high current connection to the absorbing layer can be provided from a fourth direction, for example from the z-direction or parallel from the third direction. All wirings can be individually shielded, or the low voltage supply wirings can be shielded in groups of low voltage wirings. The fewer high voltage wirings can be provided with a larger distance. In an embodiment, wiring connections to ring electrodes for electrostatic lenses are provided from the upper and lower sides alternating from electrode to electrode, to keep the distance between wirings as large as possible. FIG. 19 illustrates the embodiment at one example. A multi-beam raster unit 305, comprising 5 multi-aperture plates 304 to 306.9 and 310, each with a parallel arranged membrane in a membrane zone 199 and a support structure in a support zone 197, is mounted on a spacer 86 with the additional function of a support board. Via the support structures and the support board, high voltage wiring connections 201 are provided in positive as well as negative y-direction to the ring electrodes of the electrostatic lenses in at least one of the multi-aperture plates with the plurality of apertures 85 (only 4×5 shown). The high-voltage wiring connects are shielded by ground line 253, which is connected to ground. In a peripheral area, the high voltage wirings are shielded by coaxial shielding and isolation 255 (four high-voltage wiring connects, and coaxial shielding are shown, only one indicated by reference numbers 251 and 255). Low voltage wiring connections 257 and 259 for electrostatic stigmators and deflectors are provided from both x-directions (only positive direction shown) from ASICS 261 and 265 mounted on the support board 86. The low voltage wirings are also shielded from each other by ground wirings (not shown) between the low voltage wirings. ASICS get digital signal via digital signal line 267.1 and 267.2, as well as power supply by low voltage supply lines 269.1 and 269.2. Thereby, high voltage and low voltage signals are separates as much as possible and negative influence of mutual induction of leakage is reduced and a more reliable optical performance of the multi-beam raster unit is achieved.

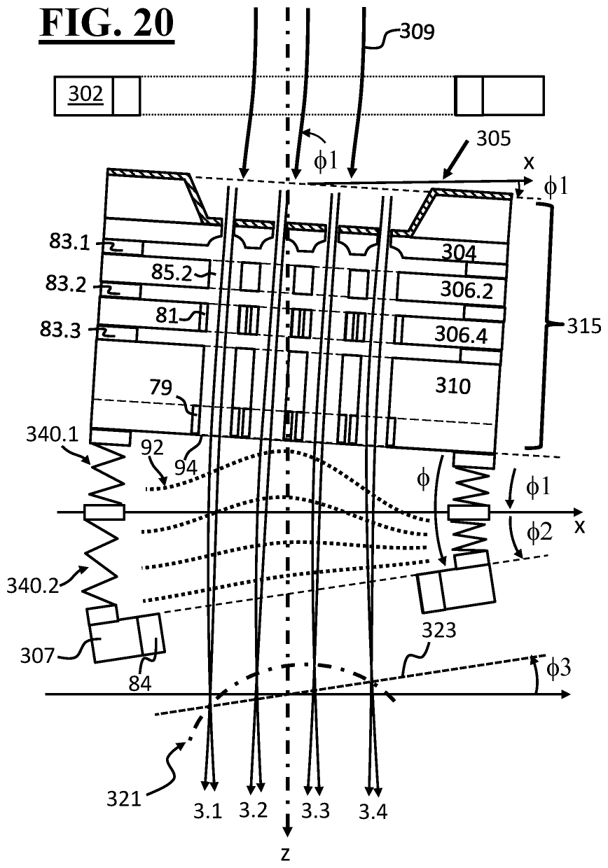

FIG. 20 illustrates another variation of the example described in FIG. 14. Opposite to the example of FIG. 14, the stack of multi-aperture plates 315 and the electrode 82 of the electrostatic condenser lens 307 are not parallel but form an angle f between each other. The electrostatic field 92, generated between the terminating multi-aperture plate 310 and the electrode 82, thus shows an asymmetry. The electrostatic field 92 penetrates the terminating apertures 94 of the terminating multi-aperture plate 310 and forms micro-lens-lets in the terminating apertures 94, which contribute to the overall focusing power of the multi-beam generating unit 305. The electrostatic micro-lens fields of the electrostatic field 92 have an asymmetry, contributing to a linear variation of the focusing power of the electrostatic micro-lens fields over the exit plane of the terminating multi-aperture plate 310. The electrostatic micro-lens fields are forming different focal lengths, including a linear component with a linear dependency of the focal length with respect to the x-coordinate. Thus, a tilt component 323 of the intermediate image surface 321 is generated in addition to the field curvature. Thus, field curvature and tilt component of angle of the image plane of the electron-optical elements arranged downstream of the charged-particle multi-beamlet generator 300 are pre-compensated. The example is not limited to the terminating multi-aperture plate 310, but can also be used in combination with a hybrid lens plate 306.5 without additional electrodes 79.

According to the example, the electrostatic condenser lens electrode 82 or the stack of multi-aperture plates 315 of the primary multi-beamlet-forming unit 305, or both, are tilted with respect to the mean propagation axis z of the plurality of primary charged particle beamlets 3 downstream of the primary multi-beamlet-forming unit 305. In the example of FIG. 20, the source 301 and collimating lenses 303 are configured such that the propagation direction of the incident beam 309 is perpendicular to the filter plate 304. In the example, the stack of multi-aperture plates 315 including the filter plate 204 and the terminating multi-aperture plate 310 is tilted with respect to the x-axis by an angle f1 and thus the incident beam 309 is inclined by the same angle f1 to the z-axis. The tilt angle f1 of the incident beam 309 can either be achieved by a mechanical tilt of source 301 and collimating lenses 303 or by the static deflector 302 arranged upstream of the filter plate 304, by which the propagation direction of the incident beam 309 can be tilted accordingly.

In the example of FIG. 20, further the electrode 84 of the electrostatic condenser lens 307 is tilted with respect to the x-axis by angle f2, and a total angle of f=f1+f2 between the terminating aperture plate 310 and the electrode 84 of the electrostatic condenser lens 307 is obtained. Thereby a tilt component 323 of the intermediate image surface 321 with an angle f3 is achieved. The angles f1 can be selected in a way that the exit plane of the terminating multi-aperture plate 310 and the plane of the tilt component 323 at angle f3 intersect each other in a line with the unit plane of the electrostatic lens field 92, which is including the micro-lens-lets formed in the apertures 94 of the terminating aperture plate 310.

According to the example, the electrostatic condenser lens electrode 82 or the stack of multi-aperture plates of the primary multi-beamlet-forming unit 305, or both can be mounted on a manipulator 340.1 or 340.2, configured for individually adjusting the tilt angles f1 and f2. With a proper adjustment of angles f1 and f2 by the at least one manipulator 340, a tilt component 323 of an intermediate image surface 321 can be adjusted. Es described above, the field curvature and tilt component 323 are subject to the imaging setting of the multi-beamlet charged-particle microscopy system 1. Especially, due to for example a different focusing power of the objective lens 203, a different rotation of the tilt component 323 might be involved. With the at least one tilt or rotation manipulator 340.2 for example for the electrode 84 of the condenser lens 307, the tilt component 323 can be adjusted or rotated to pre-compensate a different image rotation of the magnetic objective lens 102. The control unit (800) of the multi-beam charged particle microscope system (1) can therefore be configured to control during use at least one of the tilt angles f, f1, f2 in dependence of an image plane tilt according to an image setting of the multi-beam system (1).

With the improvements of the disclosure, a larger focusing range for individually focusing of a plurality of primary charged particle beamlets is achieved. An improved multi-beam generating unit of an example of the disclosure comprises at least a terminating multi-aperture plate with a plurality of individually addressable electrodes, which can form ring electrodes or multi-pole electrodes at each of the plurality of terminating apertures of the terminating multi-aperture plate. With that arrangement it is possible to individually manipulate each of the penetrating micro-lens fields, which are formed by penetration of a global electrostatic field into the terminating apertures. Thereby, as large focusing range is achieved with small individual voltage differences applied to the plurality of individually addressable electrodes.

The improved multi-beam generating unit of an example comprises at least a second or further multi-aperture plates. The plurality of multi-aperture plates can be electrically contacted to a control unit, wherein the electrical contacts can be arranged at the same side of each multi-aperture plate, for example the first of upper side or the second and bottom side of each multi-aperture plate. Some of the multi-aperture plates can comprise through connections to electrically connect a plurality of wiring connections at one side with the electrical contacts at the other side.

While a general multi-beam raster unit are described in the embodiments as multi-beam generation unit 305, the features of the embodiments are applicable as well to other multi-beam raster units, such as a multi-beam deflector or a multi-beam stigmator unit. Generally, multi-beam raster units with increased focusing range according to the examples of the disclosure can also be applied for example in the secondary beam path 11 (see FIG. 1), for example as multi-aperture corrector 220.

The features of the embodiments improve the performance of multi-beam charged particle microscopes to achieve higher resolution of below 5 nm, such as below 3 nm, for example below 2 nm or even below 1 nm. The improvements are of special relevance for a further development of multi-beam charged particle microscopes with larger numbers of the plurality of beamlets such as more than 100 beamlets, more than 300 beamlets, more than 1000 beamlets or even more than 10000 beamlets. Such multi-beam charged particle microscopes involve multi-aperture plates with larger diameter and a larger plurality of apertures and electrodes, including for example even more wiring connections. The improvements are of special relevance for routine applications of multi-beam charged particle microscopes, for example in semiconductor inspection and review, where high reliability and high reproducibility and low machine-to-machine deviations are used.

The embodiments provide a charged particle beam system which operates with a multiplicity of charged particle beams and can be used to achieve a higher imaging performance. Specifically, with the larger focusing range DF of the primary multi-beamlet-forming unit 305 of the disclosure, a narrower range of resolution for each beamlet of the plurality of beamlets is achieved. The features of the disclosure especially allow for a large range of pre-compensation of a field curvature and an image plane tilt, which is of increasing importance for multi-beam systems for planar wafer inspection tasks with increasing number of charged particle beamlets. With the features and methods described in the embodiments as well as combinations thereof, each beamlet of the plurality of beamlets is provided with beamlet diameters for example in a span from 2 nm to 2.1 nm with an average resolution of 2.05 nm, and the range of resolution achieved by the features and methods of the embodiments is below 0.15% of the average resolution, such as 0.1%, for example 0.05%.

The disclosure is not limited to the embodiments or examples described above. The embodiments or examples can be fully or partly combined with one another. As can be seen from the above explanations, numerous variations and modifications are possible, and it is evident that the scope of the present application is not limited by the specific examples.

Despite the improvements are described at the example of multi-beam charged particle microscopes, the improvements are not limited to multi-beam charged particle systems for wafer inspection, but also applicable to other multi-beam charged particle systems such as multi-beam lithography systems.

Throughout the embodiments, electrons are to be understood as charged particles in general. While some embodiments are explained at the example of electrons, they shall not be limited to electrons but well applicable to all kinds of charged particles, such as for example Helium or Neon-Ions.

The disclosure and the embodiments of the disclosure can be described by following clauses. The disclosure is however not limited to the clauses. It is understood that various combinations and modifications are possible.

Clause 1. A multi-beam generation unit (305) for a multi-beam system (1), comprising in the order of the propagation direction of an incident primary charged particle beam (309):
a filter plate (304) with a plurality of first apertures (85.1) for generating a plurality of primary charge particle beamlets (3), the filter plate (304) connected during use to a ground level;
a terminating multi-aperture plate (310) comprising a plurality of terminating apertures (94), comprising a first plurality of individually addressable electrodes (79.2, 81.2) arranged in the circumference of each one of the plurality of terminating apertures (94);
a condenser lens (307) with a condenser electrode (82, 84) with a single aperture configured for transmitting during use the plurality of primary charged particle beamlets (3);
wherein the condenser electrode (82, 84) is configured for generating during use a plurality of electrostatic micro-lens fields (92) penetrating into each of the plurality of terminating apertures (94); wherein the multi-beam generation unit (305) further comprises a control unit (830), configured to individually control the condenser electrode (82, 84) and each of the first plurality of individually addressable electrodes (79.2, 81.2) to influence the penetration depth and/or shape of each of the plurality of electrostatic micro-lens fields (92), thereby independently adjusting a lateral and/or axial focus position of each of the plurality of primary charge particle beamlets (3) on an intermediate image surface (321), in order to pre-compensate a field curvature and/or an image plane tilt of the multi-beam system (1).

Clause 2. The multi-beam generation unit (305) according to clause 1, wherein the first plurality of individually addressable electrodes (79.2, 81.2) is formed as a first plurality of electrostatic cylinder electrodes (79.2), each cylinder electrode (79.2) arranged in the circumference of one of the plurality of terminating apertures (94), configured for generating during use a suction field (88) or a depression field (90).

Clause 3. The multi-beam generation unit (305) according to clause 1, wherein the first plurality of individually addressable electrodes (79.2, 81.2) is formed as a first plurality of electrostatic multi-pole electrodes (81.2), each multi-pole electrode (81.2) arranged in the circumference of one of the plurality of terminating apertures (94), configured for generating during use a suction field (88), a depression field (90) and/or a deflection field and/or a astigmatism correction field.

Clause 4. The multi-beam generation unit (305) according to any of the previous clauses, wherein the terminating multi-aperture plate (310) comprises a first, terminating electrode layer (306.3a) comprising the first plurality of individually addressable electrodes (79.2, 81.2) and a second electrode layer (306.3b), isolated from the first plurality of individually addressable electrodes (79.2, 81.2) and arranged upstream of the first, terminating electrode layer (306.3a), the second electrode layer (306.3b) being connected during use to the ground level for forming a ground electrode layer.

Clause 5. The multi-beam generation unit (305) according to any of the clauses 1 to 3, wherein the terminating multi-aperture plate (310) is made of a single electrode layer.

Clause 6. The multi-beam generation unit (305) according to any of the previous clauses, further comprising a further multi-aperture plate configured as a first multi-stigmator plate (306.4, 306.41) being arranged upstream of the terminating multi-aperture plate (310), the first multi-stigmator plate (306.4, 306.41) having a plurality of apertures (85.4, 85.41), each comprising a second plurality individually addressable multi-pole electrodes (81, 81.1) forming a plurality of electrostatic multi-pole elements arranged in the circumference of the plurality of apertures (85.4, 85.41), each of the second individually addressable multi-pole electrodes (81, 81.1) being connected to the control unit (830), configured for deflecting, focusing or correcting of aberrations of each individual beamlet of the plurality of primary charged particle beamlets (3).

Clause 7. The multi-beam generation unit (305) according to clause 6, further comprising a further multi-aperture plate configured as a second multi-stigmator plate (306.43) being arranged upstream of the terminating multi-aperture plate (310), the second multi-stigmator plate (306.43) having a plurality of apertures (85.43), each comprising a third plurality individually addressable multi-pole electrodes (81.3) forming a plurality of electrostatic multi-pole elements arranged in the circumference of the plurality of apertures (85.43), each of the third individually addressable electrodes (81.3) being connected to the control unit (830) configured for deflecting, focusing or correcting of aberrations of each individual beamlet of the plurality of primary charged particle beamlets (3).

Clause 8. The multi-beam generation unit (305) according to any of the previous clauses, further comprising a further multi-aperture plate configured as a electrostatic lens array (306.3, 306.9) being arranged upstream of the terminating multi-aperture plate (310), the electrostatic lens array (306.3, 306.9) having a plurality of apertures (85.3, 85.9) comprising a plurality of second cylinder electrodes (79), each being individually connected to the control unit (830) configured for forming during use a plurality of electrostatic lens fields.

Clause 9. The multi-beam generation unit (305) according to clause 8, wherein the electrostatic lens array (306.3, 306.9) is a lens electrode plate (306.9) made of a single electrode layer.

Clause 10. The multi-beam generation unit (305) according to clause 8, wherein the electrostatic lens array (306.3, 306.9) is a two-layer lens-let electrode plate (306.3) with a lens electrode layer 306.3a and a ground electrode layer 306.3b.

Clause 11. The multi-beam generation unit (305) according to any of the previous clauses, wherein the condenser electrode (82, 84) is formed as a segmented electrode (84), comprising a plurality of at least four electrode segments (84.1 to 84.4), and the control unit (830) is configured to provide during us an asymmetric voltage distribution to the plurality of at least four electrode segments (84.1 to 84.4) to facilitate a focusing of the plurality of primary charged particle beamlets (3) in the curved intermediate image surface (321) with the tilt component (323).

Clause 12. The multi-beam generation unit (305) according to any of the previous clauses, further comprising at least a first ground electrode plate (306.2) with a plurality of apertures (85.2), the ground electrode plate (306.2) forming during use a first ground electrode, the ground electrode plate (306.2) being arranged between the filter plate (304) and the terminating multi-aperture plate (310).

Clause 13. The multi-beam generation unit (305) according to clause 12, further comprising a second ground electrode plate (306.8).

Clause 14. The multi-beam generation unit (305) according to any of the clauses 8 to 13, wherein the control unit (830) is configured to provide during use a plurality of individual voltages to each of the plurality of electrodes (79, 81, 79.1, 81.1, 79.2, 81.2, 81.3) of the terminating multi-aperture plate (3.10), the first multi-stigmator plate (306.4, 306.41) and/or the second multi-stigmator plate (306.43) and/or the electrostatic lens array (306.3, 306.9) to jointly form an array of individually addressable multi-stage micro lenses (316) with a individually variable focusing range variation DF of at least 6 mm, such as at least 8 mm, for example more then 10 mm for each individually addressable multi-stage micro lens (316).

Clause 15. The multi-beam generation unit (305) according to any of the previous clauses, further comprising a plurality of spacers (83.1 to 83.5) or support zones (179) for holding the plurality of multi-aperture plates (306.2 to 306.9, 310) at predetermined distances to each other.

Clause 16. The multi-beam generation unit (305) according to any of the previous clauses, wherein at least one of the plurality of multi-aperture plates (306.4 to 306.9, 310) is configured as an inverted multi-aperture plate with electrical wiring connections (175) for the plurality of individually addressable electrodes (79, 79.1, 79.2, 81, 81.1, 81.2, 81.3) at the lower or bottom side opposite to the beam entrance side of the inverted multi-aperture plate.

Clause 17. The multi-beam generation unit (305) according to clause 16, wherein the at least one inverted multi-aperture plate further comprises a plurality of through connections (149, 149.1, 149.2) for electrically contacting the plurality of individually addressable electrodes (79, 79.1, 79.2, 81, 81.1, 81.2, 81.3) via the electrical wiring connections (175) at the lower or bottom side of the inverted multi-aperture plate with contact pins (147, 147.1 147.2) arranged at the upper or beam entrance side of the inverted multi-aperture plate.

Clause 18. The multi-beam generation unit (305) according to any of the previous clauses, wherein the terminating multi-aperture plate (310) further comprises a conductive shielding layer (177.2) with the plurality of apertures (94), the conductive shielding layer (177.2) being electrically isolated from the first plurality of individually addressable electrodes (79.2, 81.2), the conductive shielding layer (177.2) arranged at the bottom side (76) of the terminating multi-aperture plate (310) between the individually addressable electrodes (79.2, 81.2) and the condenser lens (307).

Clause 19. The multi-beam generation unit (305) according to any of the previous clauses, wherein, in the propagation direction of an incident primary charged particle beam (309), the first apertures (85.1) of the filter plate (304) have a first diameter D1, and the terminating apertures (94) each have a terminating diameter DT, and wherein DT is in a range between 1.6×D1<=DT<=2.4×D1.

Clause 20. The multi-beam generation unit (305) according to clauses 6 to 19, wherein, in the propagation direction of an incident primary charged particle beam (309), the first apertures (85.1) of the filter plate 304 have a first diameter D1, the second apertures (85.2, 85.3, 85.4, 85.9) of a further multi-aperture plate (306.2, 306.3, 306.4, 306.9) have a second diameter D2, and the terminating apertures (94) have a terminating diameter DT, and wherein D1<D2<DT, such as 1.3×D1<=D2<=0.8×DT.

Clause 21. The multi-beam generation unit (305) according to clauses 6 to 20, wherein, the propagation direction of an incident primary charged particle beam (309), the first apertures (85.1) of the filter plate 206.1 have a first diameter D1, the second apertures (85.2, 85.3, 85.4, 85.9) of a second multi-aperture plate (306.2, 306.3, 306.4, 306.9) have a second diameter D2, the third apertures (85.2, 85.3, 85.4, 85.9) of a third or further multi-aperture plate (306.3, 306.4, 306.41, 306.43, 306.9) have a diameter D3 and the terminating apertures (94) have a terminating diameter DT, the multi-aperture plates being arranged in propagation direction of the primary charged particles, and wherein D1<D2<D3<DT, such as 1.4×D1<=D2<=0.9×D3<=0.8×DT.

Clause 22. A multi-aperture plate (306), comprising
a plurality of apertures (85.3, 85.4, 85.9, 94) with a plurality of isolated and individually addressable electrodes (79, 81) in an isolated electrode layer (129.1), the plurality of electrodes (79, 81) being arranged in the circumference of the apertures (85.3, 85.4, 85.9, 94);
a first conductive shielding layer (177.1) on a first side of the multi-aperture plate (306) with a first thickness T1;
a first planarized isolating layer (179.5) of a second thickness T2;
a layer of a plurality of electrical wiring connections (175) of a third thickness T3;
a second planarized isolation layer (179.3) between the electrode layer (129.1) and the layer of electrical wiring connections (175) with wiring contacts (193) formed between each of a wiring connection and an electrode (79, 81), the second planarized isolation layer (179.3) having a fourth thickness T4;

wherein the first and the second planarized isolation layers (179.5, 179.3) are made of Silicon Dioxide and are levelled down to the second and fourth thickness T2 and T4 each below 2 μm with T2<=T3<=2 μm.

Clause 23. The multi-aperture plate (306) according to clause 22, wherein each of the wiring contacts (193) is placed at an outer edge of each individually addressable electrode (79, 81), with a distance h to the inner sidewall (87) of an aperture (85, 94), wherein h is larger than h>=6 μm, such as h>8 μm, for example h>=10 μm.

Clause 24. The multi-aperture plate (306) according to any of the clauses 22 to 23, further comprising a second conductive shielding layer (177.2) on a second side of the multi-aperture plate (306) with a sixth thickness T6; and a third planarized isolation layer (129.2) formed between the second conductive shielding layer (177.2) and the electrode layer (129.1), having a fifth thickens T5<2.5 μm.

Clause 25. The multi-aperture plate (306) according to clauses 22 to 24, wherein at least one of the first or second conductive shielding layers (177.1, 177.2) have a plurality of plunging extensions (189) into each of the plurality of apertures (85, 94), forming a gap of width g to the electrodes (79, 81) with g<4 μm, such as g<=2 μm.

Clause 26. The multi-aperture plate (306) according to clauses 22 to 25, further comprising a shielding electrode layer (183) between the plurality of individually addressable electrodes (79, 81), connected to ground level (0V) for shielding the plurality of individually addressable electrodes (79, 81) from each other.

Clause 27. The multi-aperture plate (306) according to clauses 22 to 26, wherein the multi-aperture plate (306) is one of a plurality of at least two multi-aperture plates (306, 306.3, 306.4, 306.9, 310) of a multi-beam generation unit (305) configured for focusing during use a plurality of primary charged particle beamlets (3).

Clause 28. The multi-aperture plate (306) according to clauses 22 to 27, wherein the multi-aperture plate (306) is a terminating multi-aperture plate (310) with a plurality of terminating apertures (94) of a multi-beam generation unit (305), wherein each of the plurality of primary charged particle beamlets (3) exits during use the multi-beam generation unit (305) at one of the plurality of terminating apertures (94), and wherein the plurality of electrodes (79, 81) is configured for manipulating during use a plurality of penetrating micro-lens fields (92), which are penetrating during use into the plurality of terminating apertures (94).

Clause 29. The multi-aperture plate (306) according to clause 28, wherein a condenser lens (307) is arranged after the multi-aperture plate (306) being the terminating multi-aperture plate (310) of the multi-beam generation unit (305), configured for generating during use the plurality of electrostatic micro-lens fields (92) penetrating the plurality of terminating apertures (94).

Clause 30. The multi-aperture plate (306) according to clauses 22 to 29, wherein the multi-aperture plate (306) is arranged in an inverted configuration with a plurality of wiring connections (175) at a first side of the multi-aperture plate (306) and a plurality of contact pins (147) at a second side opposite to the first side of the multi-aperture plate (306), further comprising a plurality of through connections (149) for connecting the plurality of wiring connections (175) at the first side with the contact pins (147) at the second side.

Clause 31. A terminating multi-aperture plate (310), comprising:
a plurality of terminating apertures (94), configured for forming during use a plurality of electrostatic micro-lens fields (92, 92.1, 92.2) penetrating into the plurality of terminating apertures (94);
a plurality individually addressable electrodes (79.2, 81.2), the plurality of electrodes (79.2, 81.2) being arranged in the circumference of the terminating apertures (94); wherein the plurality individually addressable electrodes (79.2, 81.2) being configured to be individually connected to a control unit (830) and being configured to individually influence during use the penetration depth and/or shape of each of a plurality of electrostatic micro-lens fields (92, 92.1, 92.2).

Clause 32. The terminating multi-aperture plate (310) of clause 31, further comprising a first conductive shielding layer (177.2) at the terminating or beam exiting side (76) of the terminating multi-aperture plate (310), connected to ground level (0V) and configured for shielding the plurality of electrostatic micro-lens fields (92) from penetrating into the terminating multi-aperture plate (310), such that the plurality of electrostatic micro-lens fields (92) is penetrating during use only into the terminating apertures (94).

Clause 33. The terminating multi-aperture plate (310) of clauses 31 to 32, further comprising a shielding electrode layer (183) between the plurality of individually addressable electrodes (79.2, 81.2), connected to ground level (0V) and configured for shielding during use the plurality of individually addressable electrodes (79.2, 81.2) from each other.

Clause 34. The terminating multi-aperture plate (310) of any of the clauses 31 to 33, further comprising a plurality of wiring connections (175) for providing a plurality of individual voltages to the plurality of individually addressable electrodes (79.2, 81.2), the plurality of wiring connections (175) being configured to be connected to the control unit (830).

Clause 35. The terminating multi-aperture plate (310) of clause 34, wherein the plurality of wiring connections (175) is arranged at a first side of the terminating multi-aperture plate (310), being isolated from the conductive shielding layer (177, 177.2), and the terminating multi-aperture plate (310) further comprises a plurality of through connections (149) connected to the plurality of wiring connections (175) and being configured to be connected to the control unit (830).

Clause 36. The terminating multi-aperture plate (310) of any of the clauses 32 to 35, further comprising
a second conductive shielding layer (177.1) on an upper side of the terminating multi-aperture plate (310), wherein the upper side is the side where a plurality of charged particle beamlets (3) enters the terminating multi-aperture plate (310);
a plurality of planarized isolating layers (129.2, 179, 179.1, 179.3, 179.5);
a layer of a plurality of electrical wiring connections (175);
an electrode layer (129.1), comprising the plurality individually addressable electrodes (79.2, 81.2);

wherein each of the electrode layer (129.1), the layer of electrical wiring connections (175) and the first or second conductive shielding layer (177.2, 177.2) is isolated from an adjacent layer by one of the planarized isolating layers (129.2, 179, 179.1, 179.3, 179.5);
and wherein each of the planarized isolation layers (129.2, 179, 179.1, 179.3, 179.5) are made of Silicon Dioxide and are levelled down to a thickness T below T<3 μm, such as below T<=2.5 μm.

Clause 37. The terminating multi-aperture plate (310) of clause 36, wherein the electrode layer (129.1) has a thickness of between 50 μm and 100 μm.

Clause 38. An inverted multi-aperture plate 306, comprising
a plurality of apertures (85, 94) with a plurality of isolated and individually addressable electrodes (79, 81) in an isolated electrode layer (129.1), the plurality of electrodes (79, 81) being arranged in the circumference of the apertures (85, 94);
a first conductive shielding layer (177.1) on a first side of the multi-aperture plate (306) with a first thickness T1;
a first planarized isolating layer (179.5) of a second thickness T2;
a layer of a plurality of electrical wiring connections (175) of a third thickness T3;
a second planarized isolation layer (179.3) between the electrode layer (129.1) and the layer of electrical wiring connections (175) with through wiring contacts (193) formed between the each of a wiring connection and an electrode (79, 81), the second planarized isolation layer (179.3) having a fourth thickness T4;
a plurality of through connections (149) and contact pins (147) for contacting the plurality of electrical wiring connections (175) through the first isolated electrode layer (129.1) configured to electrically connecting the plurality of electrical wiring connections (175) on a first side of the first isolated electrode layer (129.1) with the contact pins (147) at a second, opposite side of the electrode layer (129.1).

Clause 39. The multi-aperture plate 306 according to clause 38, wherein each of the wiring contacts (193) is placed at an outer edge of each individually addressable electrode (79, 81), with a distance h to the inner sidewall (87) of an aperture (85, 94), wherein h can be larger than h>6 μm, such as h>10 μm, for example h=12 μm.

Clause 40. The multi-aperture plate 306 according to any of the clauses 38 to 39, further comprising a second conductive shielding layer (177.2) on a second side of the multi-aperture plate (306) with a sixth thickness T6; and a third planarized isolation layer (129.2) formed between the second conductive shielding layer (177.2) and the electrode layer (129.1) opposite to the second planarized isolation layer (179.3), having a fifth thickens T5, and wherein the second conductive shielding layer (177.2) comprises apertures (148) for isolating the contact pins (147) from the second conductive shielding layer (177.2).

Clause 41. The multi-aperture plate 306 according to clauses 38 to 40, wherein at least one of the first or second conductive shielding layer (177.1, 177.2) have a plurality of plunging extensions (189) into each of the plurality of apertures (85, 94), forming a gap of width g to the electrodes (79, 81) with g<4 μm, such as g<=2 μm.

Clause 42. The multi-aperture plate 306 according to clauses 38 to 41, further comprising a shielding electrode (183) between the plurality of individually addressable electrodes (79, 81), connected to ground level (0V) for shielding the plurality of individually addressable electrodes (79, 81) from each other.

Clause 43. A method of individually changing the focus distance of each of a plurality of primary charged particle beam spots (311), the method comprising
providing a plurality of individually addressable terminating electrodes (79.2, 81.2) at each of a plurality of terminating apertures (94) of a terminating multi-aperture plate (310);
providing a condenser lens electrode (82, 84) adjacent to the terminating multi-aperture plate (310) and downstream of the terminating multi-aperture plate (310) in a propagation direction of a plurality of primary charged particle beamlets (3);
providing by a control unit (830) at least a first voltage to the condenser lens electrode (82, 84) to generate a plurality of electrostatic micro-lens fields (92), which are penetrating the plurality of terminating apertures (94);
providing by the control unit (830) a plurality of individual voltages to each of the plurality of individually addressable electrodes (79.2, 81.2) and
individually controlling the plurality of individual voltages of the individually addressable terminating electrodes (79.2, 81.2) to influence the penetration depth of each of the plurality of electrostatic micro-lens fields (92), thereby independently adjusting a axial focus position of each of the plurality of primary charge particle beamlets (3) on a curved intermediate image surface (321).

Clause 44. The method of clause 43, wherein the plurality of individually addressable terminating electrodes (79.2, 81.2) are formed as first multi-pole electrodes (81.2) and further comprising the step of individually controlling the plurality of individual voltages to the first multi-pole electrodes (81.2) to influence the shape and/or lateral position of each of the plurality of electrostatic micro-lens fields (92), thereby independently adjusting a lateral focus position and shape of each of the plurality of primary charge particle beamlets (3) on the curved intermediate image surface (321).

Clause 45. The method of any of the clauses 43 to 44, wherein the step of individually controlling the plurality of individual voltages is configured to adjusting the focus position of each of the plurality of primary charge particle beamlets (3) on the curved intermediate image surface (321) with a tilt component (232).

Clause 46. The method of any of the clauses 43 to 45, further comprising
providing a first multi-stigmator plate (306.4, 306.41) with a plurality of apertures (85.4) and a plurality of individually addressable second multi-pole electrodes (81.1) upstream of the terminating multi-aperture plate (310);
providing by the control unit (830) a plurality of individual voltages to each of the plurality of individually addressable second multi-pole electrodes (81.1) and
individually controlling the plurality of individual voltages of the second multi-pole electrodes (81.1) to influence the shape and/or lateral position of each of the plurality of primary charge particle beamlets (3) before passing the plurality of terminating apertures (94) of the terminating multi-aperture plate (310).

Clause 47. The method of clause 46, further comprising
providing a second multi-stigmator plate (306.4, 306.41) with a plurality of apertures (85.4) and a plurality of individually addressable third multi-pole electrodes (81.3);
providing by the control unit (830) a plurality of individual voltages to each of the plurality of individually addressable third multi-pole electrodes (81.3) and
individually controlling the plurality of individual voltages of the third multi-pole electrodes (81.3) to influence the shape and/or lateral position and/or direction of each of the plurality of primary charge particle beamlets (3) before passing the plurality of terminating apertures (94) of the terminating multi-aperture plate (310).

Clause 48. The method of any of the clauses 43 to 47, further comprising
providing a lens-let plate (306.3, 306.9) with a plurality of apertures (85.3, 85.9) and a plurality of individually addressable ring electrodes (79);
providing by the control unit (830) a plurality of individual voltages to each of the plurality of individually addressable ring electrodes (79) and
individually controlling the plurality of individual voltages of the ring electrodes (79) to influence the focus position of each of the plurality of primary charge particle beamlets (3) before passing the plurality of terminating apertures (94) of the terminating multi-aperture plate (310).

Clause 49. The method of any of the clauses 43 to 48, further comprising individually controlling the plurality of individual voltages of the individually addressable terminating electrodes (79.2, 81.2), of any of the multi-pole electrodes (81.1, 81.3), and/or of the ring electrodes (79) of the lens-let plate (306.3, 306.9) to jointly influence the axial and lateral focus position, the shape, and the propagation direction of each of the plurality of primary charge particle beamlets (3).

Clause 50. A multi-beam generation unit (305) for a multi-beam system (1), comprising:
a filter plate (304) with a plurality of first apertures (85.1) for generating a plurality of primary charge particle beamlets (3), the filter plate (304) connected during use to a ground level;
a plurality of multi-aperture plates (306, 306.3, 306.4, 306.9), each multi aperture plate (306, 306.3, 306.4, 306.9) comprises an electrode layer (129.1) and a plurality of contact pins (147) arranged at a first side of the electrode layer (129.1),
a terminating multi-aperture plate (310); wherein each multi-aperture plate (306, 306.3, 306.4, 306.9) further comprises layer of a plurality of electrical wiring connections (175), and wherein at least one of the plurality of multi-aperture plates (306, 306.3, 306.4, 306.9) is configured as an inverted multi-aperture plate (306, 306.3, 306.4, 306.9) with the layer of a plurality of electrical wiring connections (175) arranged at the second side of the electrode layer (129.1) of the inverted multi-aperture plate (306, 306.3, 306.4, 306.9).

Clause 51. The multi-beam generation unit (305) according to clause 50, wherein the inverted multi-aperture plate (306, 306.3, 306.4, 306.9) further comprises a plurality of through connections (149) for electrically connecting the plurality of contact pins (147) with the plurality of electrical wiring connections (175).

Clause 52. The multi-beam generation unit (305) according to any of the clauses 50 to 51, wherein the terminating multi-aperture plate (310) comprises an electrode layer (129.1) with a plurality of individually addressable electrodes (79.2, 81.2), and a layer of a plurality of electrical wiring connections (175) and a plurality of contact pins (147), the plurality of contact pins (147) being arranged at a first side of the electrode layer (129.1).

Clause 53. The multi-beam generation unit (305) according to clause 52, wherein the layer of a plurality of electrical wiring connections (175) is arranged at the second side of the electrode layer (129.1) of the terminating multi-aperture plate (310).

Clause 54. The multi-beam generation unit (305) according to any of the clauses 50 to 53, further comprising a control unit (830) configured to provide a plurality of voltages to the each of the plurality of contact pins (147) of each multi-aperture plate (306, 306.3, 306.4, 306.9) and/or the terminating multi-aperture plate (310) from the same first side.

Clause 55. The multi-beam generation unit (305) according to any of the clauses 50 to 54, further comprising
a condenser lens (307) with a condenser electrode (82, 84) with a single aperture, arranged downstream of the terminating multi-aperture plate (310), configured for transmitting during use the plurality of primary charged particle beamlets (3);
the condenser electrode (82, 84) configured for generating during use a plurality of electrostatic micro-lens fields (92) penetrating each of the plurality of terminating apertures (94);
a control unit (830) configured to individually control the condenser electrode (82, 84) and each of the plurality of individually addressable electrodes (79.2, 81.2) of the terminating multi-aperture plate (310) to influence the penetration depth and/or shape of each of the plurality of electrostatic micro-lens fields (92), thereby independently adjusting a lateral and axial focus position of each of a plurality of primary charge particle beamlets (3) on a curved intermediate image surface (321).

Clause 56. A multi-beam generation unit (305) for a multi-beam system (1), comprising
a filter plate (304) with a plurality of first apertures (85.1) for generating a plurality of primary charge particle beamlets (3) from an incident primary charged particle beamlet (309);
at least a first multi-aperture plate (306.3, 306.4, 306.9) with an electrode layer (129.1);
a terminating multi-aperture plate (310) with a plurality of terminating apertures (94);
a condenser lens (307) with a condenser electrode (82, 84);
a control unit (830) configured to provide a plurality of individual voltages to the at least a first multi-aperture plate (306.3, 306.4,306.9), the terminating multi-aperture plate (310) and the condenser electrode (82, 84); and wherein the multi-beam generation unit (305) is configured for individually adjusting each of a axial focus position of each of the plurality of primary charged particle beamlets (3) with a focus range DF of more than DF>3 mm, such as DF>4 mm, including DF>6 mm, for example DF>=8 mm.

Clause 57. The multi-beam generation unit (305) according to clause 56, wherein the terminating multi-aperture plate (310) comprises a plurality of individually addressable electrodes (79.2, 81.2) arranged in the circumference of each one of the plurality of terminating apertures (94); and wherein the control unit (830) is configured to provide during use a plurality of individual voltages to each of the plurality of individually addressable electrodes (79.2, 81.2).

Clause 58. The multi-beam generation unit (305) according to any of the clauses 56 to 57, wherein the multi-beam generation unit (305) is further configured for focusing each of the plurality of primary charged particle beamlets (3) on a curved intermediate surface (321).

Clause 59. The multi-beam generation unit (305) according to clause 58, wherein the curved intermediate surface (321) has a tilt component (323).

Clause 60. The multi-beam generation unit (305) according to any of the clauses 58 to 59, wherein the multi-beam generation unit (305) is further configured for individually adjusting each of a lateral focus position of each of the plurality of primary charged particle beamlets (3) on the curved surface (321) with an accuracy below 20 nm, such as below 15 nm, for example below 10 nm.

Clause 61. The multi-beam generation unit (305) according to any of the clauses 58 to 60, wherein the multi-beam generation unit (305) is further configured for individually adjusting each of a shape or aberration of each of the plurality of primary charged particle beamlets (3) to form a plurality of stigmatic focus points (311, 311.1, 311.2, 311.3, 311.4) on the curved intermediate surface (321).

Clause 62. The multi-beam generation unit (305) according to any of the clauses 58 to 61, further comprising the step of providing a first multi-stigmator plate (306.4, 306.41) with a plurality of apertures (85.4) and a plurality of individually addressable multi-pole electrodes (81.1), wherein the control unit (830) is further configured to provide a plurality of individual voltages to each of the plurality of individually addressable multi-pole electrodes (81.1), and wherein the control unit (830) to individually control the plurality of individual voltages of the multi-pole electrodes (81.1) to influence the shape and/or lateral position of each of the plurality of primary charge particle beamlets (3) before passing the plurality of terminating apertures (94) of the terminating multi-aperture plate (310).

Clause 63. A method of fabricating a multi-aperture plate (306, 310), the method comprising
forming a plurality of electrodes (79, 81) in an electrode layer (129.1);
forming a first isolating layer (179.1) on a first side of the electrode layer (129.1), the first isolating layer (179.1) being formed of an isolating material such as Silicon dioxide;
polishing the first isolating layer (179.1) to form a first, levelled isolating layer (179.3) with a thickness below 2.5 μm;
forming and lithographically processing a layer of electrical wiring connections (175) on the first, levelled isolating layer (179.3);
forming a second isolating layer (179.4) on the layer of electrical wiring connections (175), the second isolating layer (179.4) being formed of an isolating material such as Silicon dioxide;
polishing the second isolating layer (179.4) to form a second, levelled isolating layer (179.5) with a thickness below 2.5 μm; and
forming a first conductive shielding layer (177.1) on the second, levelled isolating layer (179.5).

Clause 64. The method of clause 63, further comprising
forming a plurality of through connections (149) through the electrode layer (129.1),
forming a first isolating layer (179.1) on a second side of the electrode layer (129.1), the second side being opposite to the first side;
polishing the first isolating layer (179.1) on the second side to form a first, levelled isolating layer (179.3) with a thickness below 2.5 μm;
forming a second conductive shielding layer (177.2) on the first, levelled isolating layer (179.3) on the second side;
connecting each of the through connections on the first side with one of the electrical wiring connections (175) and on the second side with a contact pin (147).

Clause 65: The method of any of the clauses 63 to 64, further comprising:
forming a stress reduction layer (187) on the second, levelled isolating layer (179.5) on the first side, the stress reduction layer (187) being formed of Silicon Nitride (SiNX);
forming a further isolating layer (179) on the stress reduction layer (187) and polishing the further isolating layer (179) to the level the further, levelled isolating layer (179) down to a thickness of below 2.5 μm; and
forming the first conductive shielding layer (177.1) on the further, levelled isolating layer (179).

Clause 66: A multi-beam system (1), comprising
a charged particle beam source (301) and at least one collimating lens 303 for generating a collimated charged particle beam (309);
a multi-beam generation unit (305) for forming a plurality of primary charged particle beamlets (3);
a beam divider (400) for separating the plurality of primary charged particle beamlets (3) from a plurality of secondary electron beamlets (9);
an objective lens (102) for focusing the plurality of primary charged particle beamlets (3) during use on a surface (25) of a sample (7) and to collect the plurality of secondary electron beamlets (9) generated during use at the surface (25) of a sample (7);

wherein the multi-beam generation unit (305) comprises
a stack of multi-aperture plates (315), comprising at least a filter plate (304) with a plurality of first apertures (85.1) for generating a plurality of primary charged particle beamlets (3), and a hybrid or terminating multi-aperture plate (306.5, 310) comprising a plurality of terminating apertures (94); and
a condenser lens (307) with a condenser electrode (82, 84) with a single aperture configured for transmitting during use the plurality of primary charged particle beamlets (3), wherein the condenser electrode (82, 84) is configured for generating during use a plurality of electrostatic micro-lens fields (92) penetrating into each of the plurality of terminating apertures (94); and

wherein the stack of multi-aperture plates (315) and the condenser electrode (82, 84) of the condenser lens (307) form an angle f with respect to each other, the angle f deviation from 0° to pre-compensate an image plane tilt of the multi-beam system (1).

Clause 67: The system (1) according to clause 66, wherein at least one of the stack of multi-aperture plates (315) or the condenser electrode (82, 84) of the condenser lens (307) are mounted on a manipulator (340.1, 340.2) configured to adjust a tilt angle f1 of the stack of multi-aperture plates (315) or a tilt angle f2 of the condenser electrode (82, 84) of the condenser lens (307).

Clause 68: The system (1) according to clauses 66 or 67, further comprising a quasi-static deflector (302) arranged in direction of propagation of the collimated charged particle beam (309) upstream of the filter plate (304), configured to adjust the propagation angle of the collimated charged particle beam (309) to be perpendicular to a tilted stack of multi-aperture plates (315).

Clause 69: The system (1) according to any of the clauses 66 to 68, wherein the terminating aperture plate (310) comprises a first plurality of individually addressable electrodes (79.2, 81.2) arranged in the circumference of each one of the terminating apertures (94).

Clause 70: The system (1) according to any of the clauses 66 to 69, wherein the multi-beam generation unit (305) further comprises a control unit (830), configured to individually control the condenser electrode (82, 84) and each of the first plurality of individually addressable electrodes (79.2, 81.2) to influence the penetration depth and/or shape of each of the plurality of electrostatic micro-lens fields (92), thereby independently adjusting a lateral and/or axial focus position of each of the plurality of primary charged particle beamlets (3) on an intermediate image surface (321) to pre-compensate a field curvature and an image plane tilt of the multi-beam system (1).

Clause 71: The system (1) according to clauses 69 or 70, wherein the first plurality of individually addressable electrodes (79.2, 81.2) is formed as a first plurality of electrostatic cylinder electrodes (79.2), each cylinder electrode (79.2) arranged in the circumference of one of the terminating apertures (94), configured for generating during use a suction field (88) or a depression field (90).

Clause 72: The system (1) according to clauses 69 or 70, wherein the first plurality of individually addressable electrodes (79.2, 81.2) is formed as a first plurality of electrostatic multi-pole electrodes (81.2), each multi-pole electrode (81.2) arranged in the circumference of one of the plurality of terminating apertures (94), configured for generating during use a suction field (88), a depression field (90) and/or a deflection field and/or a astigmatism correction field.

Clause 73: The system (1) according to any of the clauses 66 to 72, wherein the multi-beam generation unit (305) comprises a further multi-aperture plate configured as a first multi-stigmator plate (306.4, 306.41) being arranged upstream of the terminating multi-aperture plate (310), the first multi-stigmator plate (306.4, 306.41) having a plurality of apertures (85.4, 85.41), each comprising a second plurality individually addressable multi-pole electrodes (81, 81.1) forming a plurality of electrostatic multi-pole elements arranged in the circumference of the plurality of apertures (85.4, 85.41), each of the second individually addressable multi-pole electrodes (81, 81.1) being connected to the control unit (830), configured for deflecting, focusing or correcting of aberrations of each individual beamlet of the plurality of primary charged particle beamlets (3).

Clause 74: The system (1) according to clause 73, wherein the multi-beam generation unit (305) comprises a further multi-aperture plate configured as a second multi-stigmator plate (306.43) being arranged upstream of the terminating multi-aperture plate (310), the second multi-stigmator plate (306.43) having a plurality of apertures (85.43), each comprising a third plurality individually addressable multi-pole electrodes (81.3) forming a plurality of electrostatic multi-pole elements arranged in the circumference of the plurality of apertures (85.43), each of the third individually addressable electrodes (81.3) being connected to the control unit (830) configured for deflecting, focusing or correcting of aberrations of each individual beamlet of the plurality of primary charged particle beamlets (3).

Clause 75: The system (1) according to any of the clauses 69 to 74, wherein at least one of the multi-aperture plates (306, 310) is configured as an inverted multi-aperture plate with electrical wiring connections (175) for the plurality of individually addressable electrodes (79, 81) at the lower or bottom side opposite to the beam entrance side of the inverted multi-aperture plate.

Clause 76: The system (1) according clause 75, wherein the at least one inverted multi-aperture plate further comprises a plurality of through connections (149, 149.1, 149.2) for electrically contacting the plurality of individually addressable electrodes (79, 79.1, 79.2, 81, 81.1, 81.2, 81.3) via the electrical wiring connections (175) at the lower or bottom side of the inverted multi-aperture plate with contact pins (147, 147.1 147.2) arranged at the upper or beam entrance side of the inverted multi-aperture plate.

Clause 77: The system (1) according any of the clauses 67 to 76, further comprising a control unit (800) configured to control during use at least one of the tilt angles f, f1, f2 in dependence of an image plane tilt according to an image setting of the multi-beam system (1), the image setting including an image rotation by the objective lens (102).

### A LIST OF REFERENCE NUMBERS IS PROVIDED

1 multi-beamlet charged-particle microscopy system
3 primary charged particle beamlets, or plurality of primary charged particle beamlets
5 primary charged particle beam spot
7 object
9 secondary electron beamlet, forming the plurality of secondary electron beamlets
11 secondary electron beam path
13 primary beam path
15 secondary charged particle image spot
25 Wafer surface
74 beam entrance or upper side
76 bottom side or beam exiting side
79 ring-shaped electrodes
81 multipole electrodes
82 annular electrode
83 Spacers
84 segmented ring electrode
85 apertures
86 spacer
87 inner wall of aperture
88 suction field
90 suppression field
92 electrostatic micro-lens fields (equipotential lines)
94 terminating apertures
98 layer of a conductive material
99 absorbing and conductive layer
100 object irradiation unit
101 image plane
102 objective lens
103 field lens group
105 optical axis of multi-beamlet charged-particle microscopy system
108 first beam cross over
110 collective multi-beam raster scanner
115 wafer surface
145 gap
147 soldering contacts or contact pins
148 apertures isolating contact pins from shielding layer
149 through connection
151 through holes
153 support unit
157 connecting wires to control unit
173 beam entrance or upper surface of the second multi-aperture plate
175 electrical wiring connections
177 conductive shielding layer
179 isolation material
181 isolation gap
183 bulk material, forming a shielding electrode
185 isolation gap
187 stress compensation layer
189 plunging extension
191 outer edge of ring electrode
193 opening for wiring contact
195 plurality of apertures
197 support zone
199 membrane zone
200 detection unit
205 projection system
206 electrostatic lens
207 image sensor
208 imaging lens
209 imaging lens
210 imaging lens
212 second cross over
214 aperture filter
216 active element
218 third deflection system
220 multi-aperture corrector
222 second deflection system
251 high voltage wiring connection
253 ground line
255 coaxial shielding and isolation
261 ASIC
265 ASIC
267 digital signal line
269 low voltage supply lines
300 charged-particle multi-beamlet generator
301 charged particle source
302 quasi-static deflector
303 collimating lenses
304 filter plate
305 primary multi-beamlet-forming unit
306 multi-aperture plates
306.2 ground electrode plate
306.3 two-layer lens-let plate
306.4 multi-stigmator plate
306.5 hybrid lens plate
306.8 ground electrode plate
306.9 lens electrode plate
307 first field lens
308 second field lens
309 primary electron beam
310 terminating multi-aperture plate
311 primary electron beamlet spots
315 stack of multi-aperture plates
316 multi-stage micro-lens
321 intermediate image surface
323 Intermediate image plane tilt component
331.1 upper segment
331.2 second segment
333 support zone
335 membrane zone
340 tilt or rotation manipulator
390 beam steering multi aperture plate
400 beam splitter unit
420 magnetic element
500 sample stage
503 Sample voltage supply
800 control unit
820 imaging control module
830 primary beam-path control module

What is claimed is:

1. A multi-beam generation unit, comprising in order of a propagation direction of an incident primary charged particle beam:
a filter plate comprising a plurality of first apertures configured to generate a plurality of primary charge particle beamlets, the filter plate configured to be connected to a ground level;
a terminating multi-aperture plate comprising a plurality of terminating apertures and a first plurality of individually addressable electrodes, a circumference of each terminating aperture comprising a corresponding individually addressable electrode disposed therein; and
a condenser lens comprising a condenser electrode comprising a single aperture configured to transmit the plurality of primary charged particle beamlets, the condenser electrode configured to generate a plurality of electrostatic micro-lens fields penetrating each of the plurality of terminating apertures; and
a control unit configured to individually control the condenser electrode and each of the first plurality of individually addressable electrodes to influence the penetration depth and/or shape of each of the plurality of electrostatic micro-lens fields to independently adjust a lateral and/or axial focus position of each of the plurality of primary charge particle beamlets on an intermediate image surface to pre-compensate a field curvature and/or an image plane tilt of the multi-beam system.

2. The multi-beam generation unit of claim 1, wherein the first plurality of individually addressable electrodes comprises a first plurality of electrostatic cylinder electrodes, each cylinder electrode is in the circumference of its corresponding terminating aperture to generate a suction field or a depression field during use of the multi-beam generation unit.

3. The multi-beam generation unit of claim 1, wherein the first plurality of individually addressable electrodes comprises a first plurality of electrostatic multi-pole electrodes, each multi-pole electrode in the circumference of its corresponding terminating aperture to generate a suction field, a depression field and/or a deflection field and/or an astigmatism correction field during use of the multi-beam generation unit.

4. The multi-beam generation unit of claim 1, wherein the terminating multi-aperture plate comprises:
a first, terminating electrode layer comprising the first plurality of individually addressable electrodes; and
a second electrode layer isolated from the first plurality of individually addressable electrodes,
wherein the second electrode layer is upstream of the first, terminating electrode layer, and the second electrode layer is configured to be connected to the ground level to define a ground electrode layer.

5. The multi-beam generation unit of claim 1, further comprising a further multi-aperture plate configured as a first multi-stigmator plate upstream of the terminating multi-aperture plate, wherein:
the first multi-stigmator plate comprises a plurality of apertures;
each aperture of the first multi-stigmator plate comprises a second plurality individually addressable multi-pole electrodes defining a plurality of electrostatic multi-pole elements in the circumference of the plurality of apertures; and
each second individually addressable multi-pole electrode is connected to the control unit and configured to deflect, focus or correct aberrations of each individual beamlet of the plurality of primary charged particle beamlets.

6. The multi-beam generation unit of claim 5, wherein the control unit is configured to provide a plurality of individual voltages to each of the plurality of electrodes of the terminating multi-aperture plate.

7. The multi-beam generation unit of claim 1, further comprising a further multi-aperture plate configured as a electrostatic lens array upstream of the terminating multi-aperture plate, wherein the electrostatic lens array comprises a plurality of apertures comprising a plurality of second cylinder electrodes, and each second cylinder electrode is individually connected to the control unit so that the second cylinder electrodes are configured to define a plurality of electrostatic lens fields.

8. The multi-beam generation unit of claim 1, wherein the condenser electrode comprises a segmented electrode comprising a plurality of at least four electrode segments, and the control unit is configured to provide an asymmetric voltage distribution to the at least four electrode segments to facilitate focusing of the plurality of primary charged particle beamlets in the curved and tilted intermediate image surface with the tilt component.

9. The multi-beam generation unit of claim 1, further comprising a first ground electrode plate comprising a plurality of apertures, wherein the ground electrode plate is configured to define a first ground electrode, and the ground electrode plate is between the filter plate and the terminating multi-aperture plate.

10. The multi-beam generation unit of claim 9, wherein at least one of the condenser lenses with the condenser electrode or the terminating aperture plate is mounted on a manipulator configured to adjust a tilt angle or rotation of at least one of the condenser lens with the condenser electrode or the terminating aperture plate.

11. The multi-beam generation unit of claim 1, wherein the terminating multi-aperture plate further comprises a conductive shielding layer comprising the plurality of apertures, wherein the conductive shielding layer is electrically isolated from the first plurality of individually addressable electrodes, the conductive shielding layer is at a bottom side of the terminating multi-aperture plate between the individually addressable electrodes and the condenser lens.

12. A method of individually changing the focus distance of each of a plurality of primary charged particle beam spots, the method comprising:
providing individually addressable terminating electrodes at each of a plurality of terminating apertures of a terminating multi-aperture plate;
providing a condenser lens electrode adjacent to the terminating multi-aperture plate and downstream of the terminating multi-aperture plate in a propagation direction of a plurality of primary charged particle beamlets;
using a control unit to provide a first voltage to the condenser lens electrode to generate a plurality of electrostatic micro-lens fields which penetrate the plurality of terminating apertures;
using the control unit to provide individual voltages to each of the plurality of individually addressable electrodes; and
individually controlling the plurality of individual voltages of the individually addressable terminating electrodes to influence the penetration depth of each of the plurality of electrostatic micro-lens fields to independently adjust an axial focus position of each primary charge particle beamlet on a curved intermediate image surface.

13. The method of claim 12, wherein:
the plurality of individually addressable terminating electrodes comprise first multi-pole electrodes;
the method further comprises individually controlling the plurality of individual voltages to the first multi-pole electrodes to influence the shape and/or lateral position of each electrostatic micro-lens field to independently adjust a lateral focus position and shape of each of the plurality of primary charge particle beamlets on the curved intermediate image surface.

14. The method of claim 12, wherein individually controlling the plurality of individual voltages adjusts the focus position of each of the plurality of primary charge particle beamlets on the curved intermediate image surface with a tilt component.

15. The method of claim 12, further comprising:
providing a first multi-stigmator plate comprising a plurality of apertures and a plurality of individually addressable second multi-pole electrodes upstream of the terminating multi-aperture plate;
using the control unit to provide a plurality of individual voltages to each individually addressable second multi-pole electrode; and
individually controlling the plurality of individual voltages of the second multi-pole electrodes to influence the shape and/or lateral position of each of the plurality of primary charge particle beamlets before passing the plurality of terminating apertures of the terminating multi-aperture plate.

16. The method of claim 12, further comprising:
providing a lens-let plate comprising a plurality of apertures and a plurality of individually addressable ring electrodes;
using the control unit to provide a plurality of individual voltages to each individually addressable ring electrode; and
individually controlling the plurality of individual voltages of the ring electrodes to influence the focus position of each of the plurality of primary charge particle beamlets before passing the plurality of terminating apertures f the terminating multi-aperture plate.

17. The method of claim 16, further comprising individually controlling the plurality of individual voltages of the individually addressable terminating electrodes and/or the ring electrodes to jointly influence the axial and lateral focus position, the shape, and the propagation direction of each of the plurality of primary charge particle beamlets.

18. The method of claim 12, further comprising individually controlling the plurality of individual voltages of the individually addressable terminating electrodes and/or any of the multi-pole electrodes to jointly influence the axial and lateral focus position, the shape, and the propagation direction of each of the plurality of primary charge particle beamlets.

19. A multi-beam generation unit, comprising:
a filter plate comprising a plurality of first apertures configured to generate a plurality of primary charge particle beamlets from an incident primary charged particle beamlet;
a first multi-aperture plate comprising an electrode layer;
a terminating multi-aperture plate comprising a plurality of terminating apertures;
a condenser lens comprising a condenser electrode; and
a control unit configured to provide a plurality of individual voltages to the at least a first multi-aperture plate, the terminating multi-aperture plate and the condenser electrode,
wherein the multi-beam generation unit is configured to individually adjust an axial focus position of each of the plurality of primary charged particle beamlets with a focus range DF of more than 3 mm.

20. The multi-beam generation unit of claim 19, wherein the terminating multi-aperture plate comprises a plurality of individually addressable electrodes in a circumference of each one of the plurality of terminating apertures, and the control unit is configured to provide a plurality of individual voltages to each individually addressable electrode.

21. The multi-beam generation unit of claim 19, wherein the multi-beam generation unit is configured to focus each primary charged particle beamlet on a curved intermediate surface.

22. The multi-beam generation unit of claim 21, wherein the curved intermediate surface has a tilt component.

23. The multi-beam generation unit of claim 19, wherein the multi-beam generation unit is configured to individually adjust a lateral focus position of each primary charged particle beamlet on the curved surface with an accuracy below 20 nm.

24. The multi-beam generation unit of claim 19, wherein the multi-beam generation unit is configured to individually adjust a shape or an aberration of each primary charged particle beamlet to provide a plurality of stigmatic focus points on the curved intermediate surface.

25. The multi-beam generation unit of claim 19, further comprising a first multi-stigmator plate comprising a plurality of apertures and a plurality of individually addressable multi-pole electrodes, wherein the control unit is configured to provide a plurality of individual voltages to each individually addressable multi-pole electrode, and the control unit is configured to individually control the plurality of individual voltages of the multi-pole electrodes to influence a shape and/or a lateral position of each primary charge particle beamlet before passing the plurality of terminating apertures of the terminating multi-aperture plate.
